(19) United States
(12) Patent Application Publication
(10) Pub. No.: US 2026/0231471 A1
(43) Pub. Date: Aug. 6, 2026

(54) TRANSISTOR AND DISPLAY DEVICE USING THE SAME

(71) Applicant: LG Display Co., Ltd., Seoul (KR)

(72) Inventor: Jang Dae KIM, Paju-si (KR)

(21) Appl. No.: 19/434,239

(22) Filed: Dec. 29, 2025

(30) Foreign Application Priority Data
Feb. 6, 2025 (KR) 10-2025-0015341

(51) Int. Cl. H10D 30/67; H10D 86/40; H10D 86/60; H10K 59/121

(52) U.S. Cl. CPC H10D 30/6731; H10D 30/6723; H10D 30/6757; H10D 86/441; H10D 86/60; H10K 59/1213

(57) ABSTRACT

A transistor includes an active layer on a substrate, a first metal pattern and a second metal pattern disposed beneath the active layer and spaced apart from each other by a first distance in a first direction while overlapping with the active layer, a gate electrode disposed on the active layer while overlapping with the active layer and having a width along the first direction that is greater than the first distance, a gate insulating layer between the active layer and the gate electrode, a first source-drain electrode connected to the first metal pattern and a second source-drain electrode connected to the second metal pattern and spaced apart from the first source-drain electrode.

### CROSS REFERENCE TO RELATED APPLICATIONS

Pursuant to 35 U.S.C. § 119(a), this application claims the benefit of an earlier filing date and right of priority to Korean Patent Application No. 10-2025-0015341, filed on February 6, 2025, the entire contents of which are hereby incorporated by reference as if fully set forth herein.

### TECHNICAL FIELD

The present disclosure relates to a transistor and display device using the same.

### BACKGROUND

In a TV, a monitor, a smartphone, a tablet computer, a notebook computer, etc., display devices of various types and forms are used to display an image.

Such a display device includes a plurality of pixels in order to render an image, and is provided with a transistor in order to control operation of the pixels on a pixel basis.

Such a display device, which includes a plurality of pixels, is provided with a plurality of driving and switching elements in order to drive and control the pixels. The driving and switching elements may be constituted by transistors. Such transistors are widely applied not only to pixels, but also to integrated circuits.

Recently, a variety of research and development has been conducted for an enhancement in performance of transistors and an enhancement in reliability of transistors.

### SUMMARY

In an aspect of the present disclosure, a transistor includes an active layer on a substrate, a first metal pattern and a second metal pattern disposed beneath the active layer and spaced apart from each other by a first distance in a first direction while overlapping with the active layer, a gate electrode disposed on the active layer while overlapping with the active layer and having a width along the first direction that is greater than the first distance in the first direction, a gate insulating layer between the active layer and the gate electrode, a first source-drain electrode connected to the first metal pattern and a second source-drain electrode connected to the second metal pattern and spaced apart from the first source-drain electrode.

In another aspect of the present disclosure, a display device includes a plurality of subpixels, the transistor disposed in at least one of the plurality of subpixels, a planarization layer configured to cover the transistor, and a light emitting element provided on the planarization layer.

In another aspect of the present disclosure, a display device includes a substrate including an active area including a plurality of subpixels, and a non-active area outside the active area, a plurality of gate lines and a plurality of data lines intersecting each other at the plurality of sub-pixels, a light emitting element at each of the plurality of subpixels, a pixel transistor in at least one of the plurality of subpixels; a driving circuit connected to the plurality of gate lines and disposed at the non-active area, and a driver transistor at the driving circuit. At least one of the pixel transistor and the driver transistor may include an active layer on the substrate, a first metal pattern and a second metal pattern disposed beneath the active layer and spaced apart from each other by a first distance in a first direction while overlapping with the active layer, a gate electrode disposed on the active layer while overlapping with the active layer and having a width along the first direction that is greater than the first distance, a gate insulating layer between the active layer and the gate electrode, and source-drain electrodes connected to the first metal pattern and the second metal pattern, respectively.

### BRIEF DESCRIPTION OF THE DRAWINGS

The accompanying drawings, which are included to provide a further understanding of the disclosure and are incorporated in and constitute a part of this application, illustrate implementations of the disclosure and along with the description serve to explain the principle of the disclosure. In the drawings:

FIG. 1 is a plan view showing an example of a display device according to an implementation of the present disclosure;

FIG. 2 is a sectional view showing an example of a bent state of a display panel shown in FIG. 1;

FIG. 3 is a circuit diagram showing an example of a subpixel according to an implementation of the present disclosure;

FIG. 4 is a circuit diagram showing an example of a configuration of a gate-in-panel according to an implementation of the present disclosure;

FIG. 5 is a plan view showing an example of a transistor according to a first implementation of the present disclosure;

FIG. 6 is an example of a cross-sectional view taken along line I-I’ in FIG. 5;

FIG. 7 is an example of a cross-sectional view taken along line II-II’ in FIG. 5;

FIG. 8 is a plan view showing an example of a transistor according to a second implementation of the present disclosure;

FIG. 9 is an example of a cross-sectional view taken along line III–III’ in FIG. 8;

FIG. 10 is a plan view illustrating an example of a transistor according to a third implementation of the present disclosure;

FIG. 11 is an example of a cross-sectional view taken along line IV–IV’ of FIG. 10;

FIG. 12 is a plan view showing an example of a transistor according to a fourth implementation of the present disclosure;

FIG. 13 is an example of a cross-sectional view taken along line V–V’ in FIG. 12; and

FIGS. 14 to 16 are cross-sectional views showing examples of display devices according to various implementations of the present disclosure, respectively.

### DETAILED DESCRIPTION

Implementations of the present disclosure can provide a transistor that can help prevent a variation in effective channel length and that can achieve an enhancement in reliability, and a display device including such a transistor.

In accordance with some implementations of the present disclosure, a transistor can help prevent a variation in effective channel length and/or reduce a variation in effective channel length through by utilizing a conductive metal.

In accordance with some implementations of the present disclosure, the transistor can help simplify manufacturing by mitigating the need for separate ion doping and metallization processes after formation of a gate electrode configured to define a metallization region, through provision of a conductive metal.

In accordance with some implementations of the present disclosure, a transistor can include a gate electrode that is less restricted relative to a channel region, such that the gate electrode has freedom of design in spite of overlap thereof with an active layer. This can provide a technical effect of facilitating integrated design.

In accordance with some implementations of the present disclosure, a transistor and a display device including the same are configured such that a gate electrode larger than a channel region of an active layer is provided over the active layer. This can have a technical effect of helping reduce the influence of residual hydrogen remaining in a layer over the gate electrode.

In accordance with some implementations of the present disclosure, the transistor further includes a mobility control layer configured to overlap with the channel region. This can have a technical effect of achieving high-speed driving.

In accordance with some implementations of the present disclosure, a display device can help reduce a defect rate of a transistor thereof to reduce amounts of materials such as gases, an etchant, etc. used throughout the manufacturing process for manufacture of the display device, thereby reducing greenhouse gas emissions resulting from the manufacturing process.

Objects of the present disclosure are not limited to the above-described objects, and other objects of the present disclosure not yet described will be more clearly understood by those skilled in the art from the following description.

Advantages and features of the disclosure, and implementation methods thereof, will be clarified through the following implementations described with reference to the accompanying drawings. However, the disclosure may be embodied in different forms and should not be construed as limited to the implementations set forth herein. Rather, these implementations are provided so that the disclosure will be thorough and complete, and will fully convey the scope of the disclosure to those skilled in the art. Further, the disclosure is defined only by the categories of the claims.

The same reference numerals designate the same constituent elements. Thicknesses, ratios, and dimensions of constituent elements may be exaggeratedly expressed in the drawings, for effective description of the technical content. In addition, the dimensions and scales of constituent elements shown in the drawings are different from actual dimensions and scales, for convenience of description and, as such, the dimension scales of constituent elements are not limited to those shown in the drawings.

It will be understood that, when one constituent element (or an area, a layer, a portion, or the like) is referred to as being “disposed on”, “connected to” or “coupled to” another constituent element, the one constituent element may be directly connected/coupled to the other constituent element, or a third constituent element may be disposed between the two constituent elements.

The term “and/or” is used to include one or more combinations of associated configurations.

It will be understood that, although the terms “first”, “second”, etc. may be used herein to describe various elements, these elements should not be limited by these terms. These terms are only used to distinguish one element from another. For example, a first element referred to in the following description may represent a second element, without departing from the scope of the disclosure. Similarly, the second element may represent the first element. Unless clearly used otherwise, singular expressions include a plural meaning.

Terms such as "below," "lower," "above," and "upper" are used to describe the relationships between the components shown in the drawings. These terms are relative concepts and are explained based on the orientations indicated in the drawings. For instance, unless "directly" or "immediately" is used, one or more other components may be disposed between two parts. Spatially relative terms such as "below", “beneath”, "lower," "above," and "upper" may be employed to easily describe the correlation between one device or component and other devices or components, as represented in the drawings. These spatially relative terms should be understood as encompassing different orientations of the devices when used or during operation, in addition to the directions shown in the drawings. For example, if the device in one of the drawings is turned over, elements described as "below" or "beneath" other elements would then be oriented "above" the other elements. Therefore, the exemplary term "below" may encompass both downward and upward directions.

In this specification, it is to be understood that a term, such as “include” or “have”, is intended to designate that a characteristic, a number, a step, an operation, an element, a part or a combination of them described in the specification is present, and does not preclude the presence or addition possibility of one or more other characteristics, numbers, steps, operations, elements, parts, or combinations thereof.

Features of various implementations of the present disclosure can be partially or overall coupled to or combined with each other, and can be variously inter-operated with each other and driven technically as those skilled in the art can sufficiently understand. The implementations of the present disclosure can be carried out independently from each other, or can be carried out together in a co-dependent relationship.

Hereinafter, a detailed description will be given of a transistor and a display device according to implementations of the present disclosure in conjunction with the attached drawings.

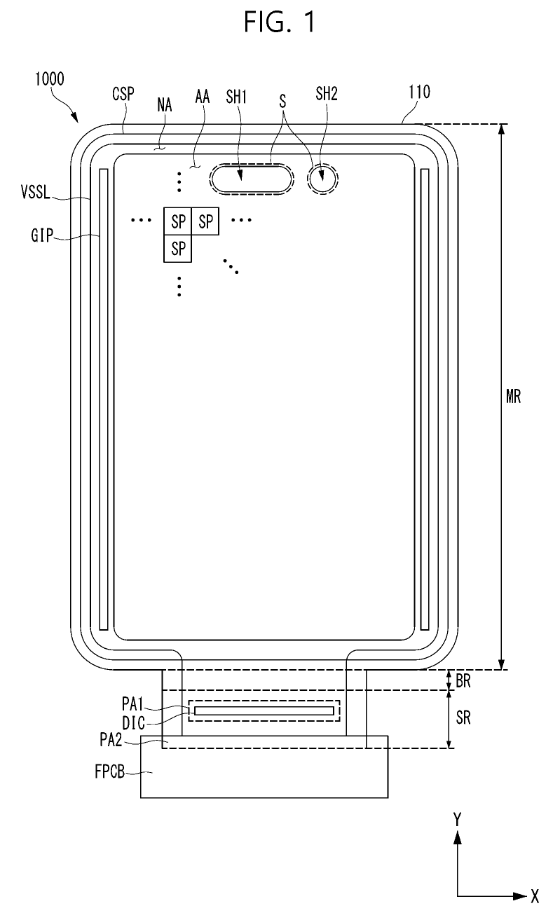

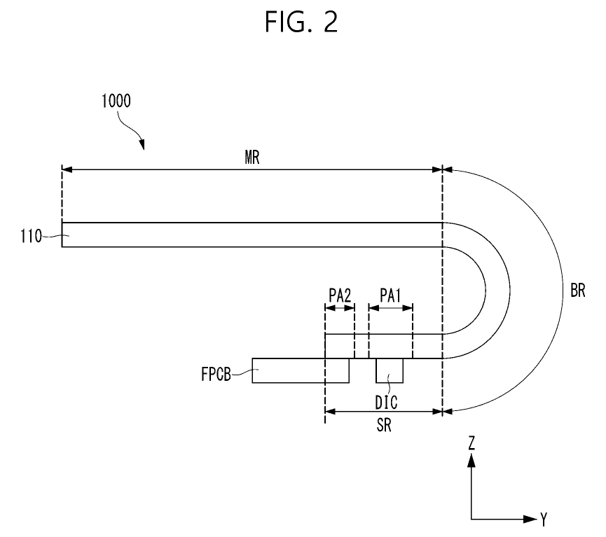

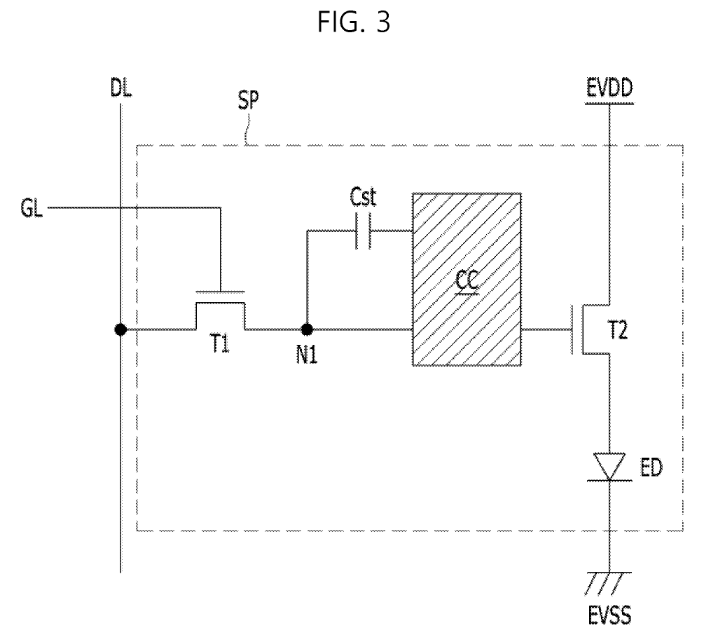

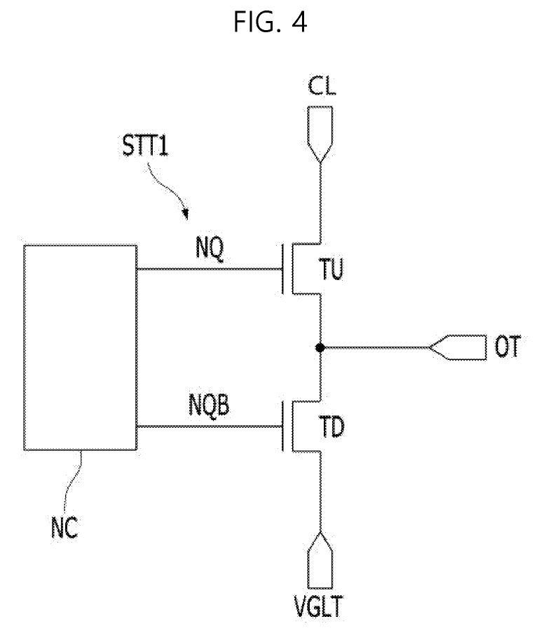

FIG. 1 is a plan view of an example of a display device according to an implementation of the present disclosure. FIG. 2 is a sectional view showing an example of a bent state of a display panel shown in FIG. 1. FIG. 3 is a circuit diagram showing an example of a subpixel according to an implementation of the present disclosure. FIG. 4 is a circuit diagram showing an example of a configuration of a gate-in-panel according to an implementation of the present disclosure.

Referring to FIG. 1, the display device 1000 may include a display panel 110. The display panel 110 may include an active area AA including a plurality of subpixels SP, and a non-active area NA around the active area AA. The planar shape of the active area AA may be a rectangular shape. However, the planar shape of the active area AA is not limited to the rectangular shape, and may also be a square shape, a circular shape, an oval shape, or other polygonal shapes. For example, the active area AA may be a rectangular shape with rounded corners, without being limited thereto, and may also be a rectangular shape with sharp corners.

In implementations, a first direction X and a second direction Y are different directions intersecting each other and, for example, represent perpendicularly-intersecting directions in a plan view. In FIG. 1, the first direction X generally corresponds to an extension direction of short sides of the display panel 110, and the second direction Y generally corresponds to an extension direction of long sides of the display panel 110. However, the directions described in the implementation should be understood as relative directions, and the implementation is not limited to the directions described.

The active area AA may include short sides extending in the first direction X and long sides extending in the second direction Y. The non-active area NA may surround the active area AA. The non-active area NA may be disposed at one side of the active area AA in the first direction X, an opposite side of the active area AA in the first direction X, one side of the active area AA in the second direction Y, and an opposite side of the active area AA in the second direction Y.

In some implementations, the display panel 110 may further include sensor holes SH1 and SH2 configured to overlap with the active area AA and to enable a sensor S to be disposed therein. The sensor S is disposed beneath the display panel 110 and may have a shape greater than that of the sensor hole. Although the sensor hole may include two sensor holes SH1 and SH2, as shown in FIG. 1, implementations of the present disclosure are not limited thereto. For example, only one sensor hole may be provided. The two sensor holes SH1 and SH2 may include a sensor hole in which an infrared sensor is disposed, and a sensor hole in which a camera sensor is disposed, but implementations of the present disclosure are not limited to these configurations. Between the sensor holes SH1 and SH2 and the active area AA, a sensor non-active area may be included. The sensor non-active area may entirely surround the sensor holes SH1 and SH2. No subpixel SP may be disposed in the sensor non-active area.

In some cases, the sensor holes SH1 and SH2 may not be disposed at the display panel 110, and the sensor S may be disposed to overlap with the display panel 110. In this case, the sensor S and the subpixels SP may partially overlap each other. The area where the sensor S overlaps with the display panel 110 will be referred to as a sensor area.

Gate-in-panels GIP may be disposed in non-active areas NA at both sides of the active area AA in the first direction X, respectively. Each gate-in-panel GIP is a gate driver configured to supply a gate voltage to gate lines GL. A low-level voltage line VSSL may be disposed outside the gate-in-panel GIP on the non-active area NA. For example, as shown in FIG. 1, the low-level voltage line VSSL may extend from a flexible printed circuit board FPCB, may pass through a sub-region SR and a bending region BR, and may be disposed outside the gate-in-panel GIP on the non-active area NA while surrounding the active area AA.

The non-active area NA disposed at the opposite side of the active area AA in the second direction Y may further extend toward an opposite side of the second direction Y from a central portion of the active area AA at the opposite side of the active area AA in the second direction Y. The width of the non-active area NA further extending toward the opposite side of the second direction Y from the central portion of the active area AA at the opposite side of the active area AA in the second direction Y may be smaller than the width in the first direction X of the non-active area NA adjacent to the opposite side of the active area AA in the second direction Y.

The display device 1000 may include a main region MR, the sub-region SR, and the bending region BR between the main region MR and the sub-region SR. The active area AA and the non-active area NA surrounding the active area AA at four sides thereof constitute the main region MR. A portion of the non-active area NA further extending toward the opposite side of the second direction Y from the central portion of the active area AA at the opposite side of the active area AA in the second direction Y may constitute the bending region BR and the sub-region SR. The bending region BR may be disposed between the sub-region SR and the main region MR. The sub-region SR may include a first pad region PA1 and a second pad region PA2 disposed at an end of the sub-region SR at the opposite side of the second direction Y. The display device 1000 may further include a data driver DIC and a flexible printed circuit board FPCB. The data driver DIC may be disposed in the first pad region PA1, and the flexible printed circuit board FPCB may be attached to the second pad region PA2. A plurality of pads, which are connected to the data driver DIC and the flexible printed circuit board FPCB, may be disposed in the first and second pad regions PA1 and PA2. The data driver DIC may take the form of a drive chip IC, without being limited thereto. Although the data driver DIC has been illustrated as being directly mounted onto the display panel 110 in a chip-on-plastic (COP) manner in an implementation, the present disclosure is not limited thereto. The data driver DIC may be disposed in a chip-on-glass (COG) manner or a chip-on-film (COF) manner.

In an implementation, the display panel 110 may further include a crack sensing pattern CSP configured to surround the low-level voltage line VSSL. As shown in FIG. 1, the crack sensing pattern CSP may be disposed to completely surround the active area AA. For example, the crack sensing pattern CSP may be disposed outside the low-level voltage line VSSL. However, implementations of the present disclosure are not limited to the above-described configuration. For example, the crack sensing pattern CSP may not be disposed in the non-active area NA at the opposite side of the active area AA in the second direction Y.

Referring to FIG. 2, in an implementation, the bending region BR of the display panel 110 in the display device 1000 may be bent in a thickness direction (or a third direction Z perpendicular to first direction X and second direction Y). This allows the main region MR and the sub-region SR to swivel relative to each other, hinged around the bending region BR, and to overlap each other in the thickness direction. The display panel 110 may be bent such that a lower surface of the main region MR and an upper surface of the sub-region SR face each other. The flexible printed circuit board FPCB may be attached to an end of the sub-region SR.

The active area AA is an area configured to display an image. In the active area AA of the display panel 110, a plurality of subpixels SP are disposed and, as such, an image may be displayed using the plurality of subpixels SP. An area other than the active area AA may constitute the non-active region NA.

The non-active area NA may be disposed in an edge area surrounding the active area AA, which displays an image. In the non-active area NA, at least one driver may be disposed to drive the plurality of subpixels SP. The driver may include a gate-in-panel GIP. The gate-in-panel GIP may be connected to a plurality of gate lines GL in the active area AA, and may sequentially supply a gate voltage signal to the plurality of gate lines GL.

In the non-active area NA, various additional elements necessary for driving of the subpixels SP in the active area AA may be further disposed.

As shown in FIG. 3, at least one of the plurality of subpixels SP may include a first transistor T1, a second transistor T2, a storage capacitor Cst, a compensation circuit CC, and a light emitting element ED.

For example, the first transistor T1 may be a switching transistor, and the second transistor T2 may be a driving transistor.

A first electrode of the first transistor T1 (for example, a drain electrode) is electrically connected to a data line DL, and a second electrode of the first transistor T1 (for example, a source electrode) is electrically connected to a first node N1. A gate electrode of the first transistor T1 is electrically connected to a gate line GL. In response to a scan signal supplied via the gate line GL, the first transistor T1 transmits, to the first node N1, a data signal supplied through the data line DL.

The storage capacitor Cst is electrically connected to the first node N1 and, as such, is charged by a voltage applied to the first node N1.

A first electrode of the second transistor T2 (for example, a drain electrode) receives a high-level drive voltage EVDD, and a second electrode of the second transistor T2 (for example, a source electrode) is electrically connected to a first electrode of the light emitting element ED (for example, an anode). The second transistor T2 may control the amount of drive current flowing through the light emitting element ED in accordance with a voltage applied to a gate electrode thereof.

A semiconductor layer of the first transistor T1 and/or the second transistor T2 may include silicon such as amorphous silicon (a-Si), polycrystalline silicon (poly-Si), low-temperature polycrystalline silicon (LT poly-Si) or the like, or an oxide such as indium-gallium-zinc oxide (IGZO) or the like, without being limited thereto. At least one of the first transistor T1 and the second transistor T2 may include an oxide semiconductor layer and, as such, may be formed at a low temperature, may maintain amorphous characteristics, and may exhibit high mobility, as compared to other materials.

The light emitting element ED outputs light corresponding to the drive current. The light emitting element ED may output light of a color corresponding to one of red, green, blue, and white.

The light emitting element ED may include the first electrode (the anode), an intermediate layer disposed on the first electrode, and a second electrode (a cathode) configured to receive a common voltage. The intermediate layer may include at least one light emitting layer and, as such, may be implemented to emit light of the same color, such as white light, on a pixel basis, or to emit different colors, such as red, green, and blue light, on a subpixel (SP) basis. The intermediate layer may include various common layers and functional layers to efficiently supply holes and electrons to the light emitting layer.

The light emitting element ED may be a front emission type diode or a bottom emission type diode.

The first electrode (anode) of the light emitting element ED is connected to the second transistor T2 and receives the drive current. The second electrode (cathode) is connected to the low-level voltage line VSSL in the non-active area NA of FIG. 1 and, as such, may receive a low-level voltage EVSS or a ground voltage.

The compensation circuit CC may be additionally provided within the subpixel SP in order to compensate the threshold voltage, etc. of the second transistor T2. The compensation circuit CC may be constituted by one or more transistors. The compensation circuit CC may include one or more transistors and a capacitor and may be diversely configured in accordance with a compensation method thereof. The subpixel SP, which includes the compensation circuit CC, may include a circuit having various structures with different numbers of transistors and/or capacitors, such as 3T1C, 4T2C, 5T2C, 6T1C, 6T2C, 7T1C, 7T2C, etc.

Among the transistors included in the subpixel, the switching transistor may require high-speed driving to enable fast switching operation.

The gate-in-panel GIP included in the non-active area NA outputs gate signals to the gate lines in response to, for example, gate control signals input from a timing controller. The gate-in-panel GIP may include a plurality of transistors, and the plurality of transistors may be formed in the same process as that of the transistors of the subpixel SP.

For example, as shown in FIG. 4, the gate-in-panel GIP may include stages STT1 connected to one another in a dependent manner, and the stages STT1 may sequentially output gate signals to the gate lines.

As shown in FIG. 4, each of the stages STT1 includes a pull-up node NQ, a pull-down node NQB, a pull-up transistor TU configured to be turned on when the pull-up node NQ is charged with a gate-high voltage, a pull-down transistor TD configured to be turned on when the pull-down node NQB is charged with a gate-high voltage, and a node controller NC configured to control charge and discharge of the pull-up node NQ and the pull-down node NQB.

The node controller NC may be connected to a start signal line, to which a start signal or a carry signal of an upstream stage is input, and a clock line, to which one of gate clock signals is input. The node controller NC controls charge and discharge of the pull-up node NQ and the pull-down node NQB in accordance with the start signal or the carry signal of the upstream stage input to the start signal line and the gate clock signal input to the clock line. In order to stably control an output of the stage STT1, the node controller NC discharges the voltage of the pull-down node NQB to be a gate-low voltage when the pull-up node NQ is charged with a gate-high voltage, and discharges the voltage of the pull-up node NQ to be a gate-low voltage when the pull-down node NQB is charged with a gate-high voltage. For these functions, the node controller NC may include a plurality of transistors.

When the stage STT1 is pulled up, for example, when the pull-up node NQ is charged with a gate-high voltage, the pull-up transistor TU is turned on, thereby outputting a gate clock signal of a clock line CL to an output terminal OT. When the stage STT1 is pulled down, for example, when the pull-down node NQB is charged with a gate-high voltage, the pull-down transistor TD is turned on, thereby outputting a gate-low voltage of a gate-low voltage terminal VGLT to the output terminal OT.

In the case of FIG. 4, each of the pull-up transistor TU, the pull-down transistor TD, and the plurality of transistors of the node controller NC in each of the stages STT1 of the gate-in-panel GIP may be a switching transistor for fast response.

In addition, although each of the pull-up transistor TU, the pull-down transistor TD, and the plurality of transistors of the node controller NC in each of the stages STT1 of the gate-in-panel GIP is illustrated in FIGS. 3 and 4 as being constituted by an N-type semiconductor transistor having N-type semiconductor characteristics, implementations of the present disclosure are not limited thereto. For example, each of the pull-up transistor TU, the pull-down transistor TD, and the plurality of transistors of the node controller NC in each of the stages STT1 of the gate-in-panel GIP may be constituted by a P-type semiconductor transistor having P-type semiconductor characteristics.

The display panel 110 may include a data driver in addition to the gate-in-panel GIP. For example, the data driver may include at least one source drive integrated circuit (referred to as “IC” hereinafter). The source drive IC receives digital video data and a source control signal from the timing controller. The source drive IC converts the digital video data into analog data voltages in accordance with the source control signal, and then supplies the analog data voltages to data lines DL.

When the source drive IC is constituted by a drive chip such as an integrated circuit, the source drive IC may be mounted on a flexible film in a chip-on-film (COF) manner. At the flexible film, wirings configured to connect the source drive IC to pads and wirings configured to connect the pads to wirings of a circuit board are formed. The flexible film is attached to pads such as data pads formed in the non-active area NA of the display panel 110, using an anisotropic conducting film and, as such, the pads and the wirings of the flexible film may be interconnected.

As described above, in the display device according to the implementation of the present disclosure, each of the sub-pixels SP includes at least one transistor as a switching element, and the gate-in-panel GIP, which is provided as a driver in the non-active area NA, includes a plurality of transistors in order to sequentially output gate signals to the gate lines. In a display device requiring fast driving due to high resolution, it is desirable for a plurality of transistors of a gate-in-panel GIP to have increased fast response in order to enable the gate-in-panel GIP to output stable gate signals.

Hereinafter, a transistor having a short channel suitable for easy application of high-resolution to the substrate of the present disclosure and exhibiting a minimal variation in effective channel length and a display device including the transistor will be described in detail.

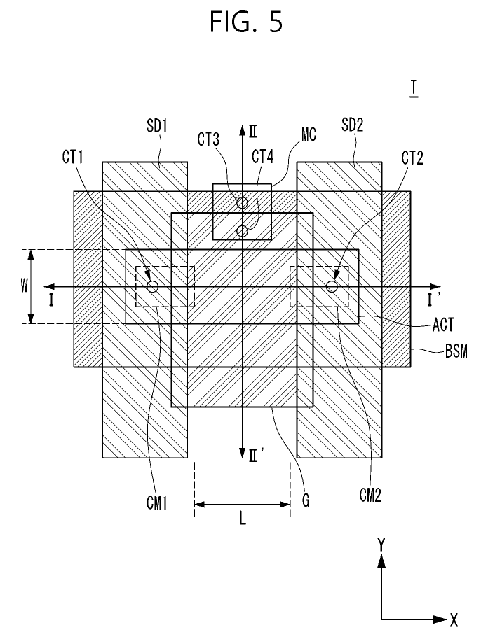

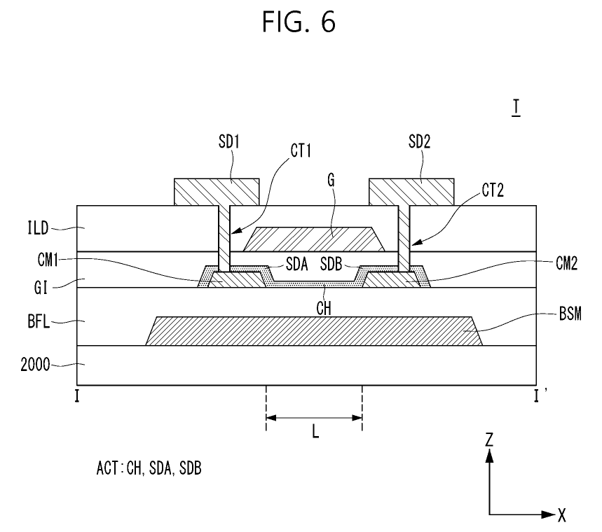

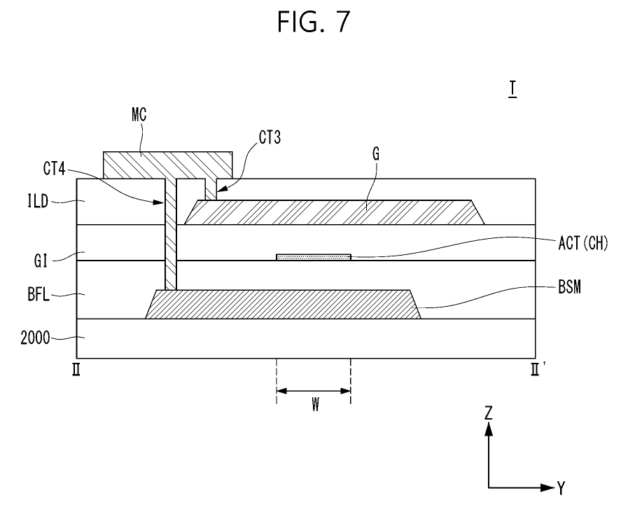

FIG. 5 is a plan view showing an example of a transistor according to a first implementation of the present disclosure. FIG. 6 is an example of a cross-sectional view taken along line I-I’ in FIG. 5. FIG. 7 is an example of a cross-sectional view taken along line II-II’ in FIG. 5.

As shown in FIGS. 5 to 7, the transistor T according to the first implementation of the present disclosure includes an active layer ACT provided on a substrate 2000, a first metal pattern CM1 and a second metal pattern CM2, which are disposed beneath the active layer ACT and are spaced apart from each other in a first direction (e.g., an X-axis direction) by a first distance L while overlapping with the active layer ACT. The transistor T further includes a gate electrode G disposed on the active layer ACT and a gate insulating layer GI that is interposed between the active layer ACT and the gate electrode G. The gate electrode G has a width along the first direction that is greater than the first distance L in the first direction, and overlaps with the active layer ACT. The transistor T further includes a first source-drain electrode SD1 connected to the first metal pattern CM1, and a second source-drain electrode SD2 connected to the second metal pattern CM2 and spaced apart from the first source-drain electrode SD1.

The first metal pattern CM1 and the second metal pattern CM2 are layers provided beneath the active layer ACT while contacting the active layer ACT. In some implementations the first and second metal patterns CM1 and CM2 are directly connected to the first and second source-drain electrodes SD1 and SD2, respectively. Accordingly, an ion impurity doping process or a metallization process for the active layer ACT may be omitted during a manufacturing process.

The first and second metal patterns CM1 and CM2 have conductive properties, and the surface of the active layer ACT facing the first and second metal patterns CM1 and CM2 may have low resistance characteristics, as compared to other regions of the active layer ACT.

In this case, the first and second metal patterns CM1 and CM2 are made of a conductive metal material. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

A channel region CH of the active layer ACT may have a channel length L corresponding to the first distance L in the first direction (e.g., an X-axis direction) between the first and second metal patterns CM1 and CM2. As such, the length L of the channel region may be defined by the arrangement of the first and second metal patterns CM1 and CM2. The channel region CH of the active layer ACT may have a width W in a second direction (e.g., a Y-axis direction), which intersects the channel length L.

Here, the first direction may be any arbitrary direction on a surface in X-Y dimensions of the substrate 2000. Accordingly, the first direction may correspond to an arrangement direction of gate lines GL or an arrangement direction of data lines DL. Alternatively, the first direction may be a diagonal direction intersecting the gate lines GL at an acute angle of less than 90°.

The first direction described below may refer to the X-axis direction, the Y-axis direction, or the diagonal direction.

The active layer ACT may contact the first metal pattern CM1 and the second metal pattern CM2 at a portion of a lower surface of the active layer ACT.

As shown in FIGS. 6 and 7, the first metal pattern CM1 and the second metal pattern CM2 may be formed as raised patterns, e.g., each forming a step structure. The active layer ACT may be disposed along the steps of upper surfaces and side surfaces of the first metal pattern CM1 and the second metal pattern CM2 in a cross-sectional view. The channel region CH of the active layer ACT can be defined as an area between the first metal pattern CM1 and the second metal pattern CM2 that neighbor each other. In some implementations, regions of the active layer ACT, which directly face and contact the first metal pattern CM1 and the second metal pattern CM2, may be defined as first and second source-drain regions SDA and SDB. Since the first and second source-drain regions SDA and SDB are in contact with the first and second metal patterns CM1 and CM2, the first and second source-drain regions SDA and SDB exhibit higher conductivity and lower resistance than those of the channel region CH of the active layer ACT in an area not in contact with the first and second metal patterns CM1 and CM2.

The active layer ACT may be configured as a single layer or as a plurality of layers with different mobilities. The active layer ACT may include an oxide semiconductor. When the active layer ACT includes a multilayer structure of oxide semiconductor layers, the oxide semiconductor layers may exhibit different mobilities.

The active layer ACT may include, for example, an oxide semiconductor material. The oxide semiconductor material may be constituted by a combination of at least one metal of zinc (Zn), indium (In), gallium (Ga), tin (Sn), and titanium (Ti) with an oxide. In some cases, a metal having high conductivity, such as iron (Fe) or the like, may be further included in the oxide semiconductor material to increase mobility.

In the display device according to some implementations of the present disclosure, the active layer ACT may exhibit different mobilities in different regions of the display device to correspond to response times of different transistors, respectively. For example, in a subpixel including a switching transistor configured to receive a gate voltage from a gate line or a light emission control signal from a light emission control line, and a driving transistor configured to supply drive current to a light emitting element, a high-mobility oxide semiconductor layer may be included in the active layer of the switching transistor in order to enable different transistors to exhibit different mobilities. For instance, among the pixel transistor included in the subpixel and the driver transistor disposed in the non-active area, a high-mobility active layer may be applied to the active layer of the driver transistor.

In some implementations, the channel region CH may be configured with a length that is greater than the first distance L between the first and second metal patterns CM1 and CM2. For example, when the active layer ACT is constituted by a plurality of layers, one or more of those layers may not directly contact the first and second metal patterns CM1 and CM2. Those one or more layers may have areas that are adjacent to inner side surfaces of the first and second metal patterns CM1 and CM2. In such scenarios, at least a portion of those areas may be used as a channel region. In this case, the channel region CH may extend not only between the first and second metal patterns CM1 and CM2, but also along the inner side surfaces of the first and second metal patterns CM1 and CM2. As such, the channel region CH may be configured to have a length corresponding to a sum of the first distance L CM2 and lengths of the inner portions of the first and second metal patterns CM1 and CM2. Accordingly, the channel length of the channel region CH may be greater than the first distance L.

The gate electrode G may completely overlap the region between the first metal pattern CM1 and the second metal pattern CM2 in the first direction, and may also overlap at least one of the first metal pattern CM1 and the second metal pattern CM2. For example, as shown in FIG. 5, the gate electrode G may be disposed to have a width (along the first direction) that is greater than the first distance L (in the first direction). Since the channel region CH within the active layer ACT is defined by the arrangement of the first and second metal patterns CM1 and CM2 beneath the active layer ACT, the arrangement of the gate electrode G is less restricted by the channel region CH. Accordingly, freedom of design of the gate electrode G may be enhanced.

Additionally, the gate electrode G is disposed over the active layer ACT under the condition that the gate electrode G has a greater area than that of the channel region CH. Accordingly, it may be possible to prevent hydrogen remaining in layers above the gate electrode G from affecting the active layer ACT. An interlayer insulating layer ILD is disposed on the gate electrode G of the transistor T. Even when residual hydrogen in the interlayer insulating layer ILD diffuses downwards during heat treatment, the gate electrode G, which has a greater area than that of the channel region CH, may effectively prevent vertical diffusion of hydrogen from the interlayer insulating layer ILD into the lower channel region CH.

As shown in FIGS. 6 and 7, the first source-drain electrode SD1 and the second source-drain electrode SD2 may be connected to the first metal pattern CM1 and the second metal pattern CM2 through a first contact hole CT1 and a second contact hole CT2 extending through the active layer ACT, respectively.

A light shielding pattern BSM overlapping with the active layer ACT may be included between the active layer ACT and the substrate 2000.

The light shielding pattern BSM is provided to prevent light introduced upwards through the substrate 2000 from affecting the active layer ACT. The light shielding pattern BSM is disposed beneath at least the active layer ACT.

A buffer layer BFL is provided between the light shielding pattern BSM and the active layer ACT. The gate electrode G, the active layer ACT, and the light shielding pattern BSM are disposed on different interlayers, respectively, to maintain electrical insulation thereamong.

As shown in FIGS. 6 and 7, the buffer layer BFL is provided between the substrate 2000 and the active layer ACT.

The gate insulating layer GI is provided between the active layer ACT and the gate electrode G.

The interlayer insulating layer ILD is provided between the gate electrode G and the first and second source-drain electrodes SD1 and SD2.

Each of the buffer layer BFL, the gate insulating layer GI, and the interlayer insulating layer ILD is an inorganic insulating layer. For example, each of the buffer layer BFL, the gate insulating layer GI, and the interlayer insulating layer ILD may include one or more inorganic insulating layers selected from a silicon oxide (SiOₓ) layer, a silicon nitride (SiNₓ) layer, and a silicon oxynitride (SiOₓN_{y}) layer, or may include a multilayer structure in which the inorganic insulating layers illustratively described above are laminated.

The first and second source-drain electrodes SD1 and SD2 are disposed above the gate electrode G. The first and second source-drain electrodes SD1 and SD2 may partially overlap with the gate electrode G, thereby increasing the degree of integration of the area where transistors are disposed.

The first contact hole CT1 is provided in an area where the first source-drain electrode SD1, the active layer ACT, and the first metal pattern CM1 overlap one another, and extends vertically through the interlayer insulating layer ILD, the gate insulating layer GI, and the active layer ACT in the area. The second contact hole CT2 is provided in an area where the second source-drain electrode SD2, the active layer ACT, and the second metal pattern CM2 overlap one another, and extends vertically through the interlayer insulating layer ILD, the gate insulating layer GI, and the active layer ACT in the area.

The first and second contact holes CT1 and CT2 are provided to expose portions of the first metal pattern CM1 and the second metal pattern CM2, respectively. The first and second contact holes CT1 and CT2 are filled with a source-drain electrode material and are spaced apart from each other. Accordingly, the first and second source-drain electrodes SD1 and SD2 may be disposed to contact the first and second metal pattern CM1 and CM2, respectively.

As shown in FIG. 7, the light shielding pattern BSM and the gate electrode G are electrically connected to each other and, as such, the light shielding pattern BSM may serve as a bottom gate. Accordingly, the transistor may have a structure including a dual gate. In this case, there is an advantage in terms of high-speed driving of the transistor in that a gate voltage is supplied to the transistor in a double manner through the light shielding pattern BSM and the gate electrode G.

In some implementations, electrical connection between the light shielding pattern BSM and the gate electrode G may be achieved through provision of a connection metal MC, that is, a connection electrode. For example, the connection metal MC may be disposed to overlap with a region of the gate electrode G and a region of the light shielding pattern BSM protruding further than the gate electrode G in a plan view. A third contact hole CT3 may be provided in a region overlapping with the gate electrode G, and a fourth contact hole CT4 may be provided in a region corresponding to the region of the light shielding pattern BSM protruding further than the gate electrode G, thereby electrically connecting the gate electrode G and the light shielding pattern BSM to each other.

The fourth contact hole CT4 may be provided to vertically extend through the interlayer insulating layer ILD, the gate insulating layer GI, and the buffer layer BFL. The third contact hole CT3 may be provided through the interlayer insulating layer ILD. The arrangement and shape of the connection metal MC shown in FIG. 5 are only examples and implementations are not limited thereto. In some cases, the connection metal MC may be omitted, and the gate electrode G may be directly connected to the light shielding pattern BSM in a region thereof not overlapping with the active layer ACT.

In the transistor shown in FIGS. 5 to 7, the first and second metal patterns CM1 and CM2 are disposed beneath the active layer ACT while directly contacting the active layer ACT. Accordingly, the exact shape of the gate electrode G does not restrict the channel region CH.

In a structure in which the gate electrode is used as a mask to define the conductive region of the active layer through plasma treatment, or in a structure in which the gate electrode is used as a mask to form doped regions in the active layer, the channel region is generally limited in size by the size of the gate electrode. After definition of the conductive region and formation of the doped regions, the size of the conductive region can expand by laterally diffusing to an area in which the active layer overlaps with the gate electrode. As a result, there can arise a problem in that the effective channel is reduced. Diffusion of the conductive region within the active layer can occur from both edges of the gate electrode G. As a result, the conductive region overlaps with the gate electrode G, in overlapping regions having a length ∆L. A variation in the length ∆L of the overlapping region may occur from both edges of the gate electrode G. Consequently, in the structure in which the gate electrode is used as a mask to define the conductive region of the active layer, the effective channel length thereof can differ from a designed channel length by 2ΔL. In a short-channel transistor, the proportion of 2ΔL relative to the designed total channel length can be large, leading to a significant negative shift variation in threshold voltage. As a result, it can be difficult to obtain stable initial characteristics and dispersion characteristics of the transistor. Additionally, when the active layer is made of a high-mobility material, the problem of a reduction in effective channel length is further exacerbated. Furthermore, as the channel width of the active layer increases, the sensitivity to negative shift of the threshold voltage increases. As a result, in the structure in which the gate electrode is used as a mask to define the conductive region, it can be difficult to realize a device with a wide channel.

The transistor according to some implementations of the present disclosure has a conductive region of the active layer which is less dependent on the gate electrode as the conductive region of the active layer, and instead is defined by the first and second metal patterns CM1 and CM2 prior to formation of the gate electrode. Accordingly, it is possible to omit a process of forming the conductive region through plasma treatment or forming doped regions using the gate electrode as a mask without requiring additional treatment. It is also possible to prevent the problem of a reduction in effective channel length from a designed channel length which can be caused by diffusion of the conductive region in the active layer occurring after additional treatment. Consequently, in accordance with implementations of the present disclosure, problems related to a variation in effective channel length may be mitigated. Thus, in a structure including a transistor having a short channel in terms of a channel length or a transistor having a wide channel in terms of channel width, it may be possible to reduce or prevent a variation in negative shift of the threshold voltage. Accordingly, initial characteristics of the transistor may be stabilized and, as such, reliability of the display device including the transistor may be enhanced.

In the transistor according to implementations of the present disclosure, it is possible to prevent formation of regions of length ΔL where the conductive region overlaps with the gate electrode G in the structure where the conductive region is defined using the gate electrode as a mask. This can help eliminate issues related to a variation in effective channel length, and prevent or alleviate a variation in threshold voltage in short-channel or wide-channel transistors, because the conductive region of the active layer is defined by the arrangement of the first and second metal patterns CM1 and CM2 contacting the lower surface of the active layer, with less dependence on exact size or shape of the gate electrode.

The transistor T according to the first implementation described above may be used as the first transistor (switching transistor) of the subpixel described with reference to FIG. 3 when the active layer has a channel with a short length. However, the transistor of the present disclosure is not limited to the above-described configuration. Transistors according to implementations of the present disclosure, in which the first and second metal patterns are provided beneath the active layer, may be used as the second transistor (driving transistor) in the subpixel. In this case, it may also be possible to prevent a variation in effective channel length, thereby enhancing the reliability of the transistor.

When the transistor T according to the first implementation described above has a wide channel, the transistor T may be included in the gate driving circuit (gate-in-panel) provided in a part of the non-active area NA. In this case, there may be an advantage in terms of high-voltage, high-speed driving in accordance with inclusion of the transistor with the wide channel.

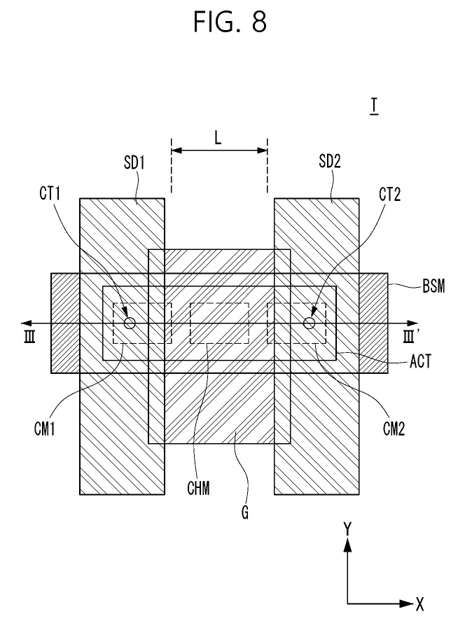

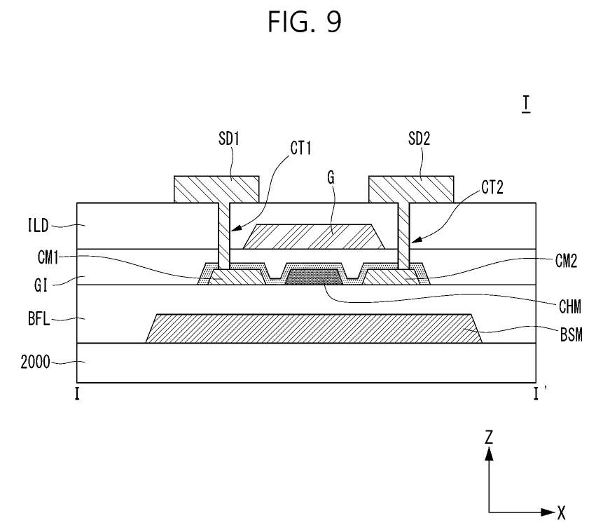

FIG. 8 is a plan view showing an example of a transistor according to a second implementation of the present disclosure. FIG. 9 is an example of a cross-sectional view taken along line III–III’ in FIG. 8.

As shown in FIGS. 8 and 9, the transistor T according to the second implementation of the present disclosure may further include a channel auxiliary layer CHM contacting the active layer ACT between the first metal pattern CM1 and the second metal pattern CM2, as compared to the transistor of the first implementation described above.

The channel auxiliary layer CHM may be disposed on the same layer as the first and second metal patterns CM1 and CM2.

Although the channel auxiliary layer CHM is disposed on the same layer as the first and second metal patterns CM1 and CM2, the channel auxiliary layer CHM may include a material different from that of the first and second metal patterns CM1 and CM2. The channel auxiliary layer CHM may include a semiconductor exhibiting higher mobility than that of the active layer ACT, thereby increasing mobility of the channel region CH.

The channel auxiliary layer CHM may include, for example, a high-mobility oxide semiconductor. Specifically, the channel auxiliary layer CHM may be made of a compound of oxygen and at least one metal of zinc (Zn), indium (In), gallium (Ga), tin (Sn), and iron (Fe).

When the mobility of the active layer ACT is, for example, 5 to 20 cm²/V·s, the mobility of the channel auxiliary layer CHM may be higher than the mobility of the active layer ACT. For instance, the mobility of the channel auxiliary layer CHM may be 1.1 to 10 times the mobility of the active layer ACT.

The channel auxiliary layer CHM may be configured to overlap with the channel region CH and, as such, the mobility of the channel region CH may be enhanced. Accordingly, the transistor T may be suitable for higher-speed driving.

A buffer layer BFL is included between the active layer ACT and the substrate 2000. The buffer layer BFL includes at least one inorganic insulating layer.

The first metal pattern CM1, the second metal pattern CM2, and the channel auxiliary layer CHM may be disposed on the buffer layer BFL while contacting the active layer ACT.

Electrical connection may be provided in an overlap region between the light shielding pattern BSM and the gate electrode G outside the active layer ACT in a plan view. Accordingly, the same gate voltage is supplied to the light shielding pattern BSM and the gate electrode G and, as such, high-speed driving may be easily achieved.

The remaining configuration of the transistor according to the second implementation, which are not described, may be identical to that of the transistor according to the first implementation.

In the transistor according to the second implementation of the present disclosure, the first and second metal patterns CM1 and CM2 spaced apart from each other are implemented beneath the active layer ACT such that the region between the first and second metal patterns CM1 and CM2 is defined as a channel region of the active layer ACT. Accordingly, a separate ion implantation or metallization process for channel formation is not required, thereby simplifying the manufacturing process. Additionally, implementation of the channel auxiliary layer CHM increases mobility of the channel, enabling high-speed driving. In particular, stable high-speed driving may be achieved in a short-channel transistor without a variation in effective channel length.

Display devices according to implementations of the present disclosure may achieve high-speed driving through provision of the transistor on the substrate to further include the channel auxiliary layer CHM disposed beneath the active layer ACT while overlapping with the channel region CH, as shown in FIGS. 8 and 9. As the transistor configured to enable high-speed driving is selectively provided in the subpixel of the substrate and the gate driver, it may be possible to achieve high-speed driving of various transistors included in the substrate.

In the transistor according to the second implementation of the present disclosure, the channel region thereof may be defined through provision of a conductive metal, with less dependence on the exact size or shape of the gate electrode. Accordingly, the effective channel length may be stabilized. When the transistor including the conductive metal is provided at a plurality of pixels on the substrate, it may be possible to prevent non-uniform variations in effective channel length among the plurality of pixels. Transistors disposed at the subpixels may also have uniform characteristics to have stable effective channels, respectively. As a result, dispersion characteristics of the transistors disposed on the substrate are stabilized, enabling reduced process margins and facilitating design of a channel with a short length.

The transistor according to the second implementation of the present disclosure has the gate electrode that can be disposed with less restriction relative to the channel region and, as such, has improved design freedom of the gate electrode overlapping with the active layer. Since the channel region may be defined by a configuration disposed beneath the active layer, the gate electrode and the first and second source-drain electrodes disposed over the active layer may have increased overlap areas thereof with the active layer. This facilitates integrated design of the transistor.

In the transistor according to the second implementation of the present disclosure, the gate electrode may be disposed to have a greater size than the channel region of the active layer. Accordingly, it may be possible to effectively prevent the active layer from being affected by residual hydrogen remaining in layers above the gate electrode.

The transistor described in implementations of the present disclosure may reduce a defect rate caused by a variation in effective channel length. Accordingly, reliability of the transistor may be enhanced.

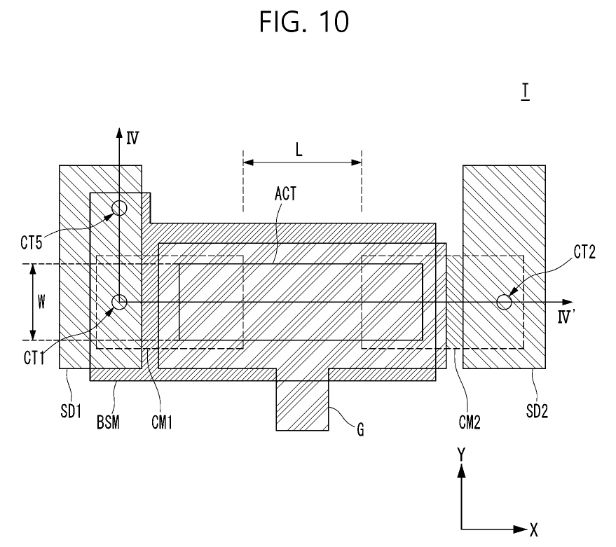

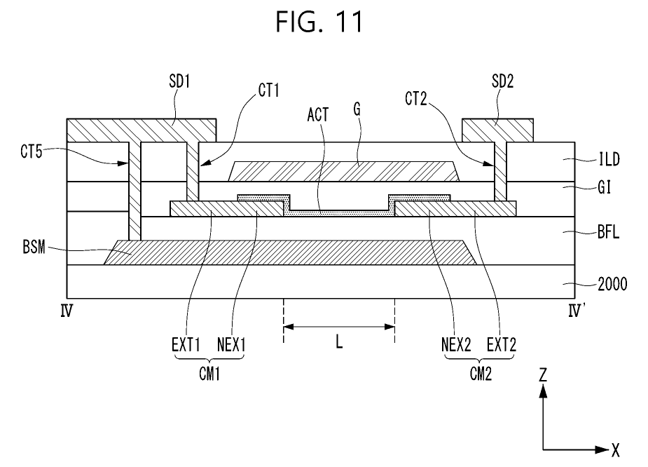

FIG. 10 is a plan view illustrating an example of a transistor according to the third implementation of the present disclosure, and FIG. 11 is an example of a cross-sectional view taken along line IV–IV’ of FIG. 10.

As shown in FIGS. 10 and 11, in the transistor according to the third implementation of the present disclosure, at least one of the first metal pattern CM1 and the second metal pattern CM2 may include an extension portion not overlapping with the active layer ACT. Referring to FIG. 11, the first metal pattern CM1 and the second metal pattern CM2 include first and second extension portions EXT1 and EXT2 disposed outside the active layer ACT, respectively.

The first metal pattern CM1 and the second metal pattern CM2 are configured to contact a lower surface of the active layer ACT.

A light shielding pattern BSM is disposed beneath the first and second metal patterns CM1 and CM2 and the active layer ACT under the condition that a buffer layer BFL is interposed therebetween.

The light shielding pattern BSM is configured to have a greater area than the active layer ACT.

The first metal pattern CM1 includes a first overlap portion NEX1 overlapping with the active layer ACT, and the first extension portion EXT1 protruding from one end of the active layer ACT.

The second metal pattern CM2 includes a second overlap portion NEX2 overlapping with the active layer ACT, and the second extension portion EXT2 protruding from the other end of the active layer ACT.

In FIGS. 10 and 11, the first and second metal patterns CM1 and CM2 are shown as extending lengthwise in the X-axis direction, whereas the first and second source-drain electrodes SD1 and SD2 are shown as extending lengthwise in the Y-axis direction.

The first extension portion EXT1 may be connected to the first source-drain electrode SD1 via a first contact hole CT1, and the second extension portion EXT2 may be connected to the second source-drain electrode SD2 via a second contact hole CT2. The first and second extension portions EXT1 and EXT2 do not overlap with the active layer ACT and, as such, can be directly connected to the first and second source-drain electrodes SD1 and SDb, which do not extend through the active layer ACT, respectively.

The first and second contact holes CT1 and CT2 may be formed through the interlayer insulating layer ILD and the gate insulating layer GI.

In this case, the gate electrode G completely overlaps with the active layer ACT, and the first and second extension portions EXT1 and EXT2 are connected to the first and second source-drain electrodes SD1 and SD2 in regions where the first and second extension portions EXT1 and EXT2 are spaced apart from the gate electrode G, respectively. Since the gate electrode G completely overlaps with the active layer ACT, the hydrogen shielding effect of the gate electrode G for the active layer ACT may be further enhanced, as compared to the first and second implementations described above.

One of the first and second source-drain electrodes SD1 and SD2 may be connected to the light shielding pattern BSM disposed therebeneath through a fifth contact hole CT5. The potential of the light shielding pattern BSM may be stabilized by a voltage signal applied to the first source-drain electrode SD1 or the second source-drain electrode SD2 connected to the light shielding pattern BSM through the fifth contact hole CT5. This is just one example, and the transistor according to the implementation of the present disclosure is not limited to the example in which the fifth contact hole CT5 is provided in the overlapping region between the light shielding pattern BSM and the first or second source-drain electrode SD1 or SD2, as shown in FIGS. 10 and 11. Similar to the previously described implementations, a modification may also be implemented to apply the same gate voltage signal as that of the gate electrode G to the light shielding pattern BSM through electrical connection between the light shielding pattern BSM and the gate electrode G.

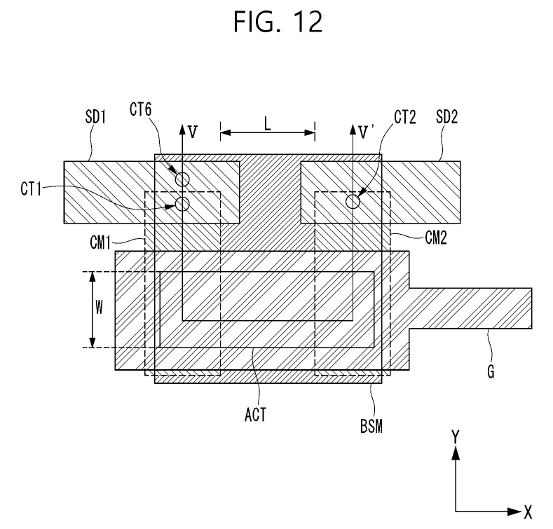

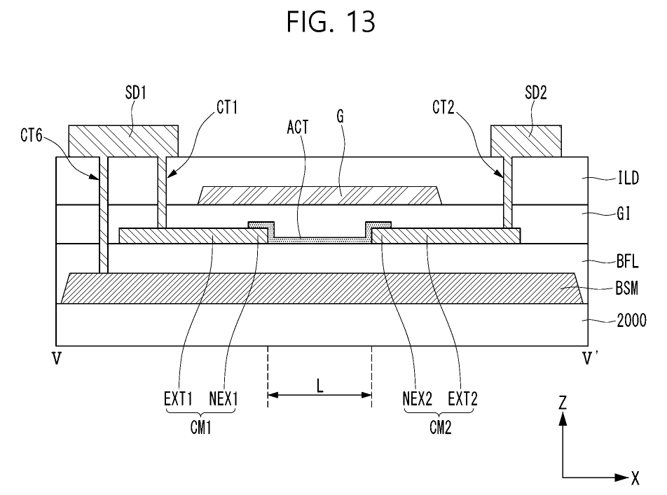

FIG. 12 is a plan view showing an example of a transistor according to a fourth implementation of the present disclosure, and FIG. 13 is an example of a cross-sectional view taken along line V–V’ in FIG. 12.

As shown in FIGS. 12 and 13, in the transistor according to the fourth implementation of the present disclosure, at least one of the first metal pattern CM1 and the second metal pattern CM2 may include an extension portion not overlapping with the active layer ACT. In addition, the first and second metal patterns CM1 and CM2 may be disposed to extend lengthwise in the Y-axis direction, whereas the first and second source-drain electrodes SD1 and SD2 may be disposed to extend lengthwise in the X-axis direction.

The first and second metal patterns CM1 and CM2 include first and second extension portions EXT1 and EXT2 disposed outside the active layer ACT, respectively.

The first metal pattern CM1 and the second metal pattern CM2 are configured to contact a lower surface of the active layer ACT.

A light shielding pattern BSM is disposed beneath the first and second metal patterns CM1 and CM2 and the active layer ACT under the condition that a buffer layer BFL is interposed therebetween.

The light shielding pattern BSM is configured to have a greater area than the active layer ACT.

The first metal pattern CM1 includes a first overlap portion NEX1 overlapping with the active layer ACT, and the first extension portion EXT1 protruding from one end of the active layer ACT.

The second metal pattern CM2 includes a second overlap portion NEX2 overlapping with the active layer ACT, and the second extension portion EXT2 protruding from the other end of the active layer ACT.

The first extension portion EXT1 may be connected to the first source-drain electrode SD1 via a first contact hole CT1, and the second extension portion EXT2 may be connected to the second source-drain electrode SD2 via a second contact hole CT2. The first and second extension portions EXT1 and EXT2 do not overlap with the active layer ACT and, as such, can be directly connected to the first and second source-drain electrodes SD1 and SD2, which do not extend through the active layer ACT, respectively.

The first and second contact holes CT1 and CT2 may be formed through the interlayer insulating layer ILD and the gate insulating layer GI.

In this case, the gate electrode G completely overlaps with the active layer ACT, and the first and second extension portions EXT1 and EXT2 are connected to the first and second source-drain electrodes SD1 and SD2 in regions where the first and second extension portions EXT1 and EXT2 are spaced apart from the gate electrode G, respectively. Since the gate electrode G completely overlaps with the active layer ACT, the hydrogen shielding effect of the gate electrode G for the active layer ACT may be further enhanced, as compared to the first and second implementations described above.

One of the first and second source-drain electrodes SD1 and SD2 may be connected to the light shielding pattern BSM disposed therebeneath through a sixth contact hole CT6. The potential of the light shielding pattern BSM may be stabilized by a voltage signal applied to the first source-drain electrode SD1 or the second source-drain electrode SD2 connected to the light shielding pattern BSM through the sixth contact hole CT6. This is just one example, and the transistor according to the implementation of the present disclosure is not limited to the example in which the sixth contact hole CT6 is provided in the overlapping region between the light shielding pattern BSM and the first or second source-drain electrode SD1 or SD2, as shown in FIGS. 12 and 13. Similarly to the previously described implementations, a modification may also be implemented to apply the same gate voltage signal as that of the gate electrode G to the light shielding pattern BSM through electrical connection between the light shielding pattern BSM and the gate electrode G.

Hereinafter, display devices according to various implementations of the present disclosure will be described with reference to specific examples.

In each of the display devices described below, transistors thereof have a configuration corresponding to a configuration included in a first transistor for switching operation or a second transistor configured to supply drive current in each subpixel. However, each of the display devices according to the above-described implementations are not limited to the above-described configuration. Modifications to the transistors according to the above-described implementations may be applied not only to transistors at subpixels, but also to transistors in the gate-in-panel provided at the non-active area NA. Additionally, such modifications may enhance high-speed driving of transistors or effects of wide-channel transistors.

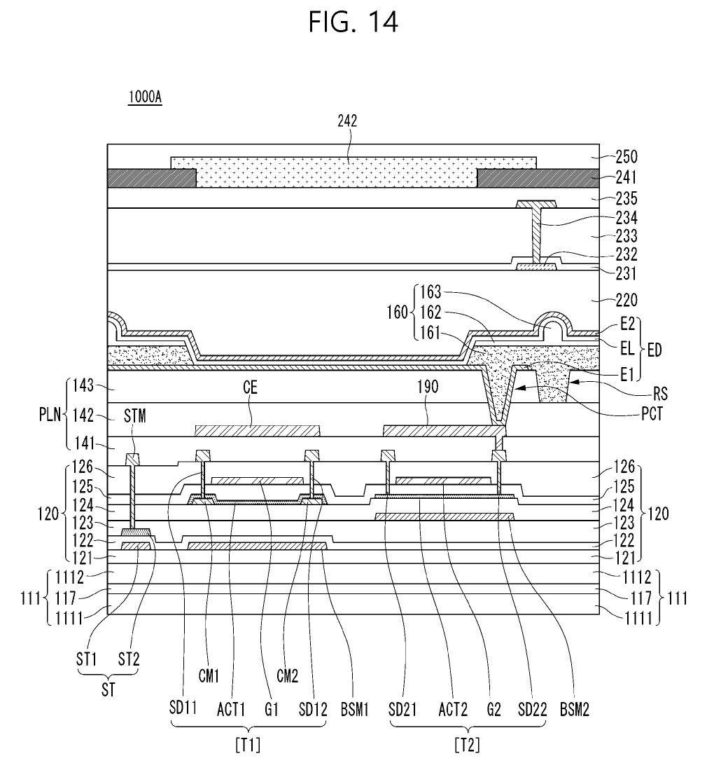

FIG. 14 is a cross-sectional view showing an example of a display device 1000A according to an implementation of the present disclosure.

Referring back to FIG. 1, the display panel 110 includes the active area AA and the non-active area NA. The display panel 110 includes a substrate 111 (see FIG. 14), and an array configuration on the substrate 111.

The substrate 2000 shown in each of FIGS. 6 to 13 may have the same configuration as that of the substrate 111 of FIG. 14, or may have a configuration including the substrate 111 and a single insulating layer or a plurality of insulating layers.

The active area AA is an area where the subpixels SP described with reference to FIG. 1 are disposed, and the non-active area NA is an area where a driver such as a gate-in-panel GIP or the like is disposed.

As shown in FIG. 14, the substrate 111 includes a plurality of subpixels SP in the active region AA thereof, and a plurality of subpixels SP may also be included within a sensor area.

The substrate 111 is made of a flexible material, which allows for easier removal thereof during laser irradiation for formation of sensor holes SH1 and SH2. For example, the substrate 111 may be constituted by first and second organic layers 1111 and 1112 overlapping each other under the condition that an inorganic interlayer insulating layer 117 is interposed therebetween. The inorganic interlayer insulating layer 117 may function to block transfer of moisture or impurities between the first and second organic layers 1111 and 1112. The inorganic interlayer insulating layer 117 is formed on the first organic layer 1111 and may include a partially-patterned structure. The inorganic interlayer insulating layer 117 may include at least one of silicon nitride, silicon oxide, and silicon oxynitride.

The first and second organic layers 1111 and 1112 may include, for example, polyimide. In addition to polyimide, the first and second organic layers 1111 and 1112 may include different organic films.

The substrate 111 may include a polyethylene terephthalate (PET) layer as one of the first and second organic layers 1111 and 1112 and a polyimide layer as the other of the first and second organic layers 1111 and 1112.

In another example, the substrate 111 may include a thin, flexible glass material having flexibility.

The substrate 111 serves to support and protect constituent elements of the display device 1000A disposed over the substrate 111.

In the active area AA and the non-active area NA of the substrate 111, a plurality of laminated insulating layers 120 (121, 122, 123, 124, 125, and 126) and a plurality of planarization layers PLN (141, 142, 143) are disposed to not only insulate metal layers G1, SD11, SD12, G2, SD21, and SD22 of transistors T1 and T2, light shielding patterns BSM1 and BSM2, and active layers ACT1 and ACT2 from one another, but also to insulate a first storage electrode ST1 and a second storage electrode ST2 constituting a storage capacitor ST from each other.

In the active area AA of the substrate 111, a first transistor T1 connected to a gate line GL (FIG. 3) and a data line DL (FIG. 3) and a second transistor T2 electrically connected to a light emitting element ED may be included. The first and second transistors T1 and T2 may be directly connected to each other, and, in some cases, may be connected to each other via a partial configuration of a compensation circuit disposed therebetween. For example, the first transistor T1 may be a switching transistor, and the second transistor T2 may be a driving transistor.

Similarly to the transistor according to the first implementation described with reference to FIGS. 5 to 7, the first transistor T1 includes a first active layer ACT1 provided on the substrate 111, a first gate electrode G1 disposed on the first active layer ACT1 while overlapping with the first active layer ACT1 under the condition that a fifth insulating layer 125 is interposed between the first active layer ACT1 and the first gate electrode G1, a first source-drain electrode SD11 connected to one side of the first active layer ACT1, and a second source-drain electrode SD12 connected to an opposite side of the first active layer ACT1 and spaced apart from the first source-drain electrode SD11.

In addition to the first active layer ACT1 provided on the substrate 111, the first transistor T1 includes a first metal pattern CM1 and a second metal pattern CM2 disposed beneath the first active layer ACT1 and spaced apart from each other by a predetermined distance in a first direction so as to overlap with the first active layer ACT1. The first gate electrode G1, which is disposed on the first active layer ACT1 while overlapping the first active layer ACT1 under the condition that the fifth insulating layer 125 is interposed between the first active layer ACT1 and the first gate electrode G1, has a width in the first direction greater than the distance between the first and second metal patterns CM1 and CM2. The first source-drain electrode SD11 is connected to the first metal pattern CM1, and the second source-drain electrode SD12, which is spaced apart from the first source-drain electrode SD11, is connected to the second metal pattern CM2.

The first metal pattern CM1 and the second metal pattern CM2 are layers provided to contact a lower surface of the first active layer ACT1. The first metal pattern CM1 and the second metal pattern CM2 are directly connected to the first and second source-drain electrodes SD11 and SD12, respectively. Through this structure, the first gate electrode G1 is less restricted by the conductive region of the first active layer ACT1 and, as such, may be disposed to overlap with the entire region between the first and second metal patterns CM1 and CM2 and portions of the first and second metal patterns CM1 and CM2. Accordingly, in the display device 1000A according to FIG. 14, the first transistor T1 omits the metallization process using the gate electrode as a mask and, as such, it may be possible to eliminate reduction and variation of an effective channel region occurring in a structure requiring the metallization process using the gate electrode as a mask.

The first and second metal patterns CM1 and CM2 have electrical conductivity, and regions of the first active layer ACT1 contacting the first and second metal patterns CM1 and CM2 may have low-resistance characteristics, as compared to other regions of the first active layer ACT1.

In the display device 1000A shown in FIG. 14, the first transistor T1 functions as a switching transistor. For this function, the first transistor T1 includes the first active layer ACT1 contacting upper surfaces of the first and second metal patterns CM1 and CM2.

In the display device 1000A shown in FIG. 14, for at least the first transistor T1, the metallization process is omitted, and the channel length is defined by the distance between the first and second metal patterns CM1 and CM2 beneath the first active layer ACT1, with less dependence on the first gate electrode G1. Since the first and second metal patterns CM1 and CM2, which are conductive materials, directly contact the first active layer ACT1, it may be possible to prevent a variation in effective channel length, ΔL, generated during the metallization process and to stably secure the effective channel length of the transistor.

Since the first gate electrode G1 overlaps with the first and second metal patterns CM1 and CM2, the first active layer ACT1 may be protected from influence of hydrogen present above the first active layer ACT1. A first light shielding pattern BSM1 may be provided beneath the first active layer ACT1. The first light shielding pattern BSM1 may prevent light introduced upwards through the substrate 111 from affecting the first active layer ACT1.

A plurality of insulating layers 122, 123, and 124 may be provided between the first active layer ACT1 and the first light shielding pattern BSM1. The plurality of insulating layers 122, 123, and 124 between the first active layer ACT1 and the first light shielding pattern BSM1 may function as a buffer layer BFL (FIG. 6) configured to planarize a surface on which the first active layer ACT1 will be formed in association with the first transistor T1. In some cases, the first light shielding pattern BSM1 may be connected to the first gate electrode G1 in order to receive the same gate voltage signal as that the first gate electrode G1. In this case, the first transistor T1 has an effect obtained in a double-gate transistor, which is advantageous for high-speed driving.

The second transistor T2 includes a second active layer ACT2 provided on the substrate 111, a second gate electrode G2 disposed on the second active layer ACT2 while overlapping with the second active layer ACT2 under the condition that the fifth insulating layer 125 is interposed between the second active layer ACT2 and the second gate electrode G2, and a third source-drain electrode SD21 and a fourth source-drain electrode SD22 connected to opposite sides of the second active layer ACT2, respectively.

A second light shielding pattern BSM2 may be provided beneath the second active layer ACT2 to prevent light introduced upwards through the substrate 111 from affecting the second active layer ACT2.

The fifth insulating layer 125 is disposed between the first and second active layers ACT1 and ACT2 and the first and second gate electrodes G1 and G2 in the first and second transistors T1 and T2 and, as such, functions as a gate insulating layer.

As shown in FIG. 14, in the display device 1000A according to the implementation of the present disclosure, at least the first transistor T1 among the transistors T1 and T2 provided in each subpixel includes the first and second metal patterns CM1 and CM2 described above with reference to FIGS. 5 to 13, which are provided to contact the first active layer ACT1. This configuration may prevent a variation in effective channel length in a transistor structure with a short channel length. As shown in FIG. 14, the first transistor T1, which includes the first and second metal patterns, and the second transistor T2, which does not include the first and second metal patterns, may have different channel lengths.

In the non-active area NA of the substrate 111, a third transistor having the same configuration as the first transistor T1 may be included. For example, the third transistor may be included in a gate-in-panel GIP and may be a buffer transistor with high output. When the third transistor is included in the gate-in-panel GIP, the third transistor may be electrically connected to the gate line GL to receive a gate voltage signal.

On the active area AA and the non-active area NA, a plurality of laminated insulating layers 120 (121, 122, 123, 124, 125, and 126) are disposed to insulate electrodes constituting the first and second transistors T1 and T2 and the active layers ACT1 and ACT2 from one another. The insulating layers 120 may include a first insulating layer 121, a second insulating layer 122, a third insulating layer 123, a fourth insulating layer 124, a fifth insulating layer 125, and a sixth insulating layer 126.

In addition to the shown first and second transistors T1 and T2, another transistor with an active layer provided at a layer different from those of the first and second transistors T1 and T2 may be provided in a portion of the active area AA or the non-active area NA of the substrate 111. At least one of the first to fourth insulating layers 121, 122, 123, and 124 may function as a buffer layer or an interlayer insulating layer for an active layer other than the active layers ACT1 and ACT2 of the first and second transistors T1 and T2, such as an active layer including polysilicon.

The first insulating layer 121 is disposed on the active area AA and the non-active area NA of the substrate 111. The first insulating layer 121 may be referred to as a buffer layer and may perform the same function as a buffer layer known in the technical field. The first insulating layer 121 is disposed on the substrate 111 to protect the structures disposed above the substrate 111 from moisture penetrating through the substrate 111 and to planarize the surface of the substrate 111.

The first insulating layer 121 is disposed to extend up to an edge of the substrate 111 to prevent moisture from penetrating through the edge of the substrate 111. The first insulating layer 121 may be constituted by a single inorganic layer or a plurality of inorganic layers laminated in an alternating manner.

For example, the first insulating layer 121 may include one or more inorganic layers selected from a silicon oxide (SiOₓ) layer, a silicon nitride (SiNₓ) layer, and a silicon oxynitride (SiOₓN_{y}) layer, or may include a multilayer structure in which the inorganic insulating layers illustratively described above are laminated.

A first light shielding pattern BSM1 made of a conductive metal material may be provided on the first insulating layer 121. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first light shielding pattern BSM1 may constitute one electrode of a storage capacitor included in the subpixel.

The second insulating layer 122 may be disposed on the first insulating layer 121 on which the first light shielding pattern BSM1 is disposed. The second insulating layer 122 may function as an insulator of a storage capacitor connected to at least one of the first transistor T1 and the second transistor T2. Alternatively, the second insulating layer 122 may serve as an interlayer insulating layer of a transistor including a polycrystalline silicon semiconductor layer.

The second insulating layer 122 may include an inorganic material. The inorganic material may include, for example, a silicon nitride (SiNₓ) layer.

The third insulating layer 123 may be disposed on the second insulating layer 122. The third insulating layer 123 may function as a buffer layer for the first transistor T1. The third insulating layer 123 may include an inorganic layer, for example, a silicon oxide (SiOₓ) layer, a silicon nitride (SiNₓ) layer, a silicon oxynitride (SiOₓN_{y}) layer, or multiple layers thereof. In some cases, the second insulating layer 122 may also be used as a gate insulating layer for a transistor including a polycrystalline silicon semiconductor layer.

A second light shielding pattern BSM2 made of a conductive metal material is disposed on the third insulating layer 123. Specifically, the conductive metal material may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first and second light shielding patterns BSM1 and BSM2 may each be disposed on the same layer as one of first and second electrodes of a storage capacitor or a capacitor. The first and second light shielding patterns BSM1 and BSM2 may each be a single layer or may each have a laminated structure of a plurality of different metal materials.

The fourth insulating layer 124 may be disposed on the third insulating layer 123 provided with the second light shielding pattern BSM2. The fourth insulating layer 124 is disposed below the first and second active layers ACT1 and ACT2 and may function as a buffer layer. The fourth insulating layer 124 may also serve to planarize surfaces of regions where the first and second active layers ACT1 and ACT2 will be disposed on the fourth insulating layer 124.

The fourth insulating layer 124 may include an inorganic material. The inorganic material may include, for example, a silicon oxide (SiOₓ) layer or a multilayer structure in which inorganic layers are laminated.

The first to fourth insulating layers 121, 122, 123, and 124 may be used as a buffer layer, a gate insulating layer, and an interlayer insulating layer for the transistor including polycrystalline silicon on the substrate.

On the fourth insulating layer 124, the first and second metal patterns CM1 and CM2, which are spaced apart from each other, are provided in regions overlapping with the first light shielding pattern BSM1.

The first and second metal patterns CM1 and CM2 are made of a conductive metal material. Specifically, the conductive metal material may include at least one of at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

As an oxide semiconductor material is deposited on the fourth insulating layer 124 and is then selectively removed, the first active layer ACT1 is disposed along upper surfaces of the first and second metal patterns CM1 and CM2, side surfaces of the first and second metal patterns CM1 and CM2, and an upper surface of the fourth insulating layer 124 between neighboring side surfaces of the first and second metal patterns CM1 and CM2, and the second active layer ACT2 is disposed on an upper surface of the fourth insulating layer 124 in a region spaced apart from the first active layer ACT1.

As shown in FIG. 5, a channel region CH of the first active layer ACT1 may have a channel length L corresponding to a first distance L in a first direction (e.g., an X-axis direction). The channel region CH of the first active layer ACT1 may also have a width W in a second direction (e.g., a Y-axis direction) intersecting the channel length L.

The oxide semiconductor material may be constituted by a combination of at least one metal of zinc (Zn), indium (In), gallium (Ga), tin (Sn), and titanium (Ti) with an oxide. In some cases, a metal having high conductivity, such as iron (Fe) or the like, may be further included in the oxide semiconductor material to increase mobility.

Examples of the oxide semiconductor material may include zinc oxide (ZnO), zinc-tin oxide (ZTO), indium-zinc oxide (ZIO), indium oxide (InO), titanium oxide (TiO), indium-gallium-zinc oxide (IGZO), indium-zinc-tin oxide (IZTO), iron-indium-zinc oxide (FIZO), etc.

The fifth insulating layer 125 is disposed to cover the first active layer ACT1 and the second active layer ACT2. The fifth insulating layer 125 functions as a gate insulating layer.

On the fifth insulating layer 125, the first and second gate electrodes G1 and G2 are disposed to partially overlap with the first active layer ACT1 and the second active layer ACT2, respectively. The first and second gate electrodes G1 and G2 may each include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). The first and second gate electrodes G1 and G2 may each be constituted by a single layer or a plurality of layers.

The first gate electrode G1 is disposed on the first active layer ACT1 to have a width greater than the distance between the first and second metal patterns CM1 and CM2. The first gate electrode G1 overlaps with the region between the first and second metal patterns CM1 and CM2 and portions of the first active layer ACT1 disposed over portions of the first and second metal patterns CM1 and CM2.

The first gate electrode G1 may be connected to, for example, the gate line GL described with reference to FIG. 3.

In an implementation of the present disclosure, the first gate electrode G1 is connected to a first light shielding pattern BSM1 disposed therebeneath and, as such, may receive a gate voltage signal with the same potential as that of the first light shielding pattern BSM1. In this case, the first transistor T1 may achieve high-speed switching with a small size in accordance with potential stability of the first light shielding pattern BSM1 and application of a dual-gate structure of the first light shielding pattern BSM1 together with the first gate electrode G1.

For example, a first storage electrode ST1 may be further provided on the first insulating layer 121 at the same layer as that of the first light shielding pattern BSM1, and a second storage electrode ST2 overlapping with the first storage electrode ST1 may be provided on the second insulating layer 122.

The sixth insulating layer 126 is disposed on the fifth insulating layer 125 on which the first and second gate electrodes G1 and G2 are disposed.

The sixth insulating layer 126 is formed of an inorganic insulating material. In some cases, the sixth insulating layer 126 may be a single layer.

For example, the sixth insulating layer 126 may include a silicon oxide (SiOₓ) layer or a silicon nitride (SiNₓ) layer, or may include a multilayer structure in which inorganic layers are laminated.

In the region of the second transistor T2, contact holes are formed by selectively removing the sixth insulating layer 126 and the fifth insulating layer 125 to expose portions of the second active layer ACT2. Additionally, in the region of the first transistor T1, contact holes are formed by selectively removing the sixth insulating layer 126, the fifth insulating layer 125, and the first active layer ACT1 to expose the first and second metal patterns CM1 and CM2.

A metal material is formed on the sixth insulating layer 126 such that the metal material fills respective contact holes to provide the third source-drain electrode SD21 and the fourth source-drain electrode SD22, which are connected to the second active layer ACT2 through the metal material, and the first and second source-drain electrodes SD11 and SD12, which are directly connected to the first and second metal patterns CM1 and CM2.

The first to fourth source-drain electrodes SD11, SD12, SD21, and SD22 may include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Each of the first to fourth source-drain electrodes SD11, SD12, SD21, and SD22 may be constituted by a single layer or a plurality of layers.

A storage connection electrode STN connected to the second storage electrode ST2 may also be provided on the same layer as that of the first to fourth source-drain electrodes SD11, SD12, SD21, and SD22.

A first planarization layer 141 may be provided on the first to fourth source-drain electrodes SD11, SD12, SD21, and SD22 to protect the first and second transistors T1 and T2.

A cover electrode CE and a connection electrode 190 may be further provided on the first planarization layer 141 in regions corresponding to the first and second transistors T1 and T2, respectively, to prevent light incident from above the first and second transistors T1 and T2 or operation of the light emitting element ED from affecting the transistors.

The cover electrode CE and the connection electrode 190 may be formed at the same layer on the first planarization layer 141 using the same conductive material. The connection electrode 190 may be electrically connected to the light emitting element ED disposed thereover. In some cases, the cover electrode CE and the connection electrode 190 may be omitted. When the connection electrode 190 is omitted, the fourth source-drain electrode SD22 of the second transistor T2 may be connected to the light emitting element ED.

A second planarization layer 142 and a third planarization layer 143 may be sequentially provided on the cover electrode CE and the connection electrode 190.

The first, second, and third planarization layers 141, 142, and 143 may include an organic material. The organic material may include one or more of acryl resin, phenolic resin, polyimide resin, unsaturated polyester resin, polyamide resin, benzocyclobutene, polyphenylene resin, and polyphenylene sulfide resin. The first to third planarization layers 141, 142, and 143 may collectively be referred to as a planarization layer PLN in terms of a planarization function thereof.

A first electrode E1 functioning as an anode may be further provided on the planarization layer PLN. The first electrode E1 may be connected to the fourth source-drain electrode SD22 via a contact hole PCT in the third planarization layer 143 and the second planarization layer 142 and via the connection electrode 190.

The first electrode E1, an intermediate layer EL, and a second electrode E2, which are sequentially laminated on the planarization layer PLN, constitute the light emitting element ED.

One of the first electrode E1 and the second electrode E2 may include a reflective electrode, whereas the other of the first electrode E1 and the second electrode E2 may include a transparent electrode or a reflective-transmissive electrode.

When the first electrode E1 includes a reflective electrode, the first electrode E1 may function to prevent light from entering a transistor disposed therebeneath.

The first electrode E1 may be constituted by a laminated structure of, for example, a first transparent electrode, a reflective electrode, and a second transparent electrode. In this case, the second transparent electrode, which is an uppermost electrode of the first electrode E1, may act as a dielectric to reduce an energy barrier for hole injection at an interface between the first electrode E1 and the intermediate layer EL. In this case, the first and second transparent electrodes may each be a transparent oxide electrode made of indium tin oxide (ITO), indium zinc oxide (IZO), or the like. The reflective electrode may include a material such as silver, a silver-based alloy such as an Ag-Pd-Cu (APC) alloy, aluminum, or an aluminum alloy.

For example, the first electrode E1 may be formed to have a multilayer structure such as a laminated structure of aluminum (Al) and titanium (Ti) (Ti/Al/Ti), a laminated structure of aluminum (Al) and ITO (ITO/Al/ITO), a laminated structure of an Ag-Pd-Cu (APC) alloy and ITO (ITO/APC/ITO), a laminated structure of silver (Ag) and a molybdenum-titanium alloy (Ag/MoTi), or may include a single-layer structure constituted by one of silver (Ag), aluminum (Al), molybdenum (Mo), gold (Au), magnesium (Mg), calcium (Ca), and barium (Ba), or an alloy of two or more thereof.

A pixel defining layer 160 is disposed to surround an edge of the first electrode E1. A light emitting part may be defined in an open area of the pixel defining layer 160. The pixel defining layer 160 may extend into the non-active area NA and may have a region at least partially overlapping with the gate-in-panel GIP.

The pixel defining layer 160 may include an inorganic material or an organic material. For example, the pixel defining layer 160 may include a first bank layer 161, a second bank layer 162, and a spacer 163. For example, at least one of the first bank layer 161, the second bank layer 162, and the spacer 163 may include an opaque material (e.g., a black material) to prevent light interference between adjacent subpixels SP. In this case, the opaque material may include a light shielding material constituted by at least one of a color pigment, organic black, and carbon. For example, the first bank layer 161 may be formed of an opaque organic material (organic black), whereas the second bank layer 162 and the spacer 163 may be formed of a transparent material. The second bank layer 162 may be disposed to completely cover the first bank layer 161. The spacer 163 may be disposed on a portion of the second bank layer 162.

The third planarization layer 143 may have a recess RS extending downwards from an upper surface of the third planarization layer 143 at a portion of the third planarization layer 143 overlapping with the pixel defining layer 160. In some cases, the recess RS may extend throughout the entire thickness of the second planarization layer 142 beneath the third planarization layer 143 or may extend to a part of the thickness of the second planarization layer 142. Additionally, the first bank layer 161 of the pixel defining layer 160 may fill the recess RS. In some cases, the recess RS may extend throughout the entire thickness of the second planarization layer 142. The material of the first bank layer 161 provided in the recess RS may shield light that is totally internally reflected on the substrate.

The intermediate layer EL may include a hole injection layer, a hole transport layer, a light emitting layer, an electron transport layer, and an electron injection layer. The intermediate layer EL may be formed to have a tandem structure including a plurality of stacks each including a hole transport layer, a light emitting layer, and an electron transport layer under the condition that a charge generation layer is disposed between adjacent ones of the stacks. The charge generation layer may include, for example, an n-type charge generation layer and a p-type charge generation layer.

The light emitting layer included in the intermediate layer EL may be configured such that light emitting layers are different at different sub-pixels, respectively. The light emitting layer may be constituted by a red light emitting layer configured to emit red light, a green light emitting layer configured to green light, or a blue light emitting layer configured to blue light. For example, patterned red, green, and blue light emitting layers may be disposed on the first electrode E1 at different sub-pixels SP, respectively.

For example, the red light emitting layer may be disposed at a red sub-pixel in a patterned manner, the green light emitting layer may be disposed at a green sub-pixel in a patterned manner, and the blue light emitting layer may be disposed at a blue sub-pixel in a patterned manner. However, implementations of the present disclosure are not limited to the above-described conditions, and at least two organic light emitting layers of the red light emitting layer, the green light emitting layer, and the blue light emitting layer may be disposed at one sub-pixel SP in a stacked manner.

In some cases, the light emitting layer may be a white light emitting layer configured to emit white light. In this case, the light emitting layer may not take the form of a pattern at sub-pixels SP, but may take the form of a common layer disposed at sub-pixels SP in common while including one or more layers.

As described above, the intermediate layer EL may be disposed to have a tandem structure of two or more stacks. In this case, each light emitting element ED may include a charge generation layer disposed between adjacent ones of the stacks. The charge generation layer may take the form of a common layer disposed at a top surface of the active area AA.

The second electrode E2 may be formed by laminating a transmissive electrode made of, for example, ITO, IZO, or the like, or a reflective transmissive electrode made of, for example, silver, a silver alloy, magnesium, a magnesium alloy, ytterbium (Yb), an ytterbium alloy, or the like. The second electrode E2 may be formed to have a small thickness in order to enhance transmittance. The second electrode E2 may be a common layer disposed at sub-pixels SP in common to receive the same voltage. To this end, the second electrode E2 may be disposed to extend from the active area AA to a portion of the non-active area NA.

The second electrode E2 may be a transmissive electrode. The second electrode E2 may include a transparent conductive material (for example, a transparent conductive oxide (TCO)) through which light may pass, such as ITO or IZO, or a semi-transmissive conductive material such as magnesium (Mg), silver (Ag), or an alloy of magnesium (Mg) and silver (Ag). When the second electrode E2 is constituted by a semi-transmissive conductive material, light emission efficiency may be enhanced by virtue of a microcavity effect.

Heretofore, a top-emission type light emitting element has been described as an example of the light emitting element ED. However, the light emitting element ED of the present disclosure is not limited to the above-described type, and may have a bottom-emission type in which light emitted from the intermediate layer ED is discharged toward the substrate 111. In this case, the first electrode E1 may be constituted by a transparent or translucent electrode material, and the second electrode E2 may be constituted by a reflective electrode material.

A capping layer (not shown) may be formed on the second electrode E2 to protect the second electrode E2 of the light emitting element ED and to enhance the light extraction efficiency toward an upper side.

An encapsulation layer 220 may be disposed on the light emitting element ED. The encapsulation layer 220 covers the active area AA and the non-active area NA and, as such, may prevent oxygen or moisture from penetrating the light emitting element ED. If necessary, other layers such as the capping layer, etc. may be interposed between the encapsulation layer 220 and the second electrode E2.

The encapsulation layer 220 may be constituted by a plurality of layers. The encapsulation layer 220 may be constituted by a structure in which an inorganic layer including an inorganic insulating material and an organic layer including an organic insulating material are alternately laminated. For example, the inorganic insulating material may include one or more materials such as silicon oxide, silicon nitride and/or silicon oxynitride, etc.

The organic insulating material may include one or more materials selected from the group consisting of polyethylene terephthalate, polyethylene naphthalate, polycarbonate, polyimide, polyethylene sulfonate, polyoxymethylene, polyarylate, and hexamethyldisiloxane.

A touch sensor may be further configured on the encapsulation layer 220.

The touch sensor may include a touch buffer layer 231, a bridge electrode 232, a touch intermediate insulating layer 233, a sensor electrode layer 234, and a touch protective layer 235.

A light shielding layer 241 corresponding to a non-light emitting part, a color filter 242 corresponding to the light emitting part, and an upper protective layer 250 may be further configured on an upper surface of the touch protective layer 235 of the touch sensor.

In the active area AA of the substrate 111, the first transistor T1 connected to the gate line GL (FIG. 3) and the data line DL (FIG. 3) and the second transistor T2 electrically connected to the light emitting element ED may be included. The first and second transistors T1 and T2 may be directly connected to each other, and, in some cases, may be connected to each other via a partial configuration of a compensation circuit disposed therebetween. For example, the first transistor T1 may be a switching transistor, and the second transistor T2 may be a driving transistor.

Although FIG. 14 shows the transistor according to the first implementation as the structure of the first transistor T1, the present disclosure is not limited to this example. For example, as shown in FIGS. 10 to 13, in the structure of the first transistor T1, the first and second metal patterns CM1 and CM2 may include first and second extension portions EXT1 and EXT2 protruding to the outside of the first active layer ACT1 such that the first and second metal patterns CM1 and CM2 are connected to the first and second source-drain electrodes SD11 and SD12 at the first and second extension portions EXT1 and EXT2, respectively.

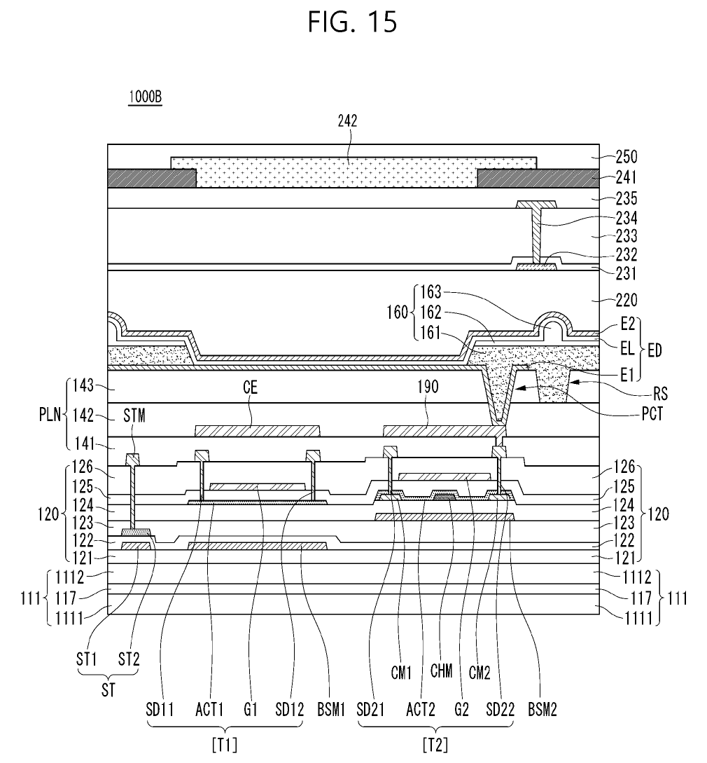

Hereinafter, a display device 1000B, in which the transistor according to the second implementation according to FIGS. 8 and 9 is applied to the second transistor T2, will be described with reference to FIG. 15.

The display device 1000B according to the implementation of FIG. 15 additionally includes first and second metal patterns CM1 and CM2 disposed beneath a second active layer ACT2 of the second transistor T2, and a channel auxiliary layer CHM in a region between the first and second metal patterns CM1 and CM2.

The display device 1000B of FIG. 15 differs from the display device 1000A of FIG. 14 in terms of first and second transistors T1 and T2, and is identical to the display device 1000A of FIG. 14 in terms of configurations disposed above and beneath the first and second transistors T1 and T2. Accordingly, no description of the same configurations will be given.

In the display device 1000B shown in FIG. 15, the first transistor T1 functions as a switching transistor, and the second transistor T2 may function as a driving transistor.

In the display device 1000B according to the implementation of FIG. 15, the first transistor T1 includes a first active layer ACT1 provided on a substrate 111, a first gate electrode G1 disposed on the first active layer ACT1 while overlapping with the first active layer ACT1 under the condition that a fifth insulating layer 125 is interposed between the first active layer ACT1 and the first gate electrode G1, a first source-drain electrode SD11 connected to one side of the first active layer ACT1, and a second source-drain electrode SD12 connected to an opposite side of the first active layer ACT1 and spaced apart from the first source-drain electrode SD11.

The second transistor T2 includes the second active layer ACT2 provided on the substrate 111, a first metal pattern CM1 and a second metal pattern CM2 disposed beneath the second active layer ACT2 and spaced apart from each other by a first distance L in a first direction while overlapping with the second active layer ACT2, a second gate electrode G2 disposed on the second active layer ACT2 while overlapping with the second active layer ACT2 and having a width greater than the first distance L in the first direction under the condition that the fifth insulating layer 125 is interposed between the second active layer ACT2 and the second gate electrode G2, a third source-drain electrode SD21 connected to the first metal pattern CM1, and a fourth source-drain electrode SD22 connected to the second metal pattern CM2 and spaced apart from the third source-drain electrode SD21.

Additionally, in the second transistor T2, the channel auxiliary layer CHM, which is disposed beneath the second active layer ACT2 and spaced apart from the first and second metal patterns CM1 and CM2 in a region between the first and second metal patterns CM1 and CM2, may be further included. The channel auxiliary layer CHM may include a high-mobility oxide semiconductor.

The first metal pattern CM1 and the second metal pattern CM2 are layers provided beneath the second active layer ACT2 to contact the second active layer ACT2. The first metal pattern CM1 and the second metal pattern CM2 are directly connected to the third and fourth source-drain electrodes SD21 and SD22, respectively. Through this structure, the second gate electrode G2 is less restricted by a conductive region of the second active layer ACT2 and, as such, may be disposed to overlap with the entire region between the first and second metal patterns CM1 and CM2 and portions of the first and second metal patterns CM1 and CM2. Accordingly, it may be possible to omit the metallization process using the gate electrode as a mask and, as such, it may be possible to eliminate reduction and variation of an effective channel region occurring in a structure requiring the metallization process using the gate electrode as a mask.

The first and second metal patterns CM1 and CM2 have electrical conductivity, and surfaces of the second active layer ACT2 contacting the first and second metal patterns CM1 and CM2 may have low-resistance characteristics, as compared to other regions of the second active layer ACT2.

The channel auxiliary layer CHM may include an oxide semiconductor material exhibiting higher mobility than that of the second active layer ACT2 disposed on the channel auxiliary layer CHM.

In the second transistor T2, the second active layer ACT2 is configured such that a lower surface thereof contacts the first and second metal patterns CM1 and CM2 and the channel auxiliary layer CHM in different regions. The channel auxiliary layer CHM in the channel region may enhance high-speed performance of the second transistor T2 and may increase on-current Ion of the second transistor as a driving transistor.

The first and second active layers ACT1 and ACT2 may include the same oxide semiconductor material and, as such, may be formed through the same process.

As an oxide semiconductor material is deposited on a fourth insulating layer 124 and is then selectively removed, the second active layer ACT2 is disposed along upper surfaces and side surfaces of the first and second metal patterns CM1 and CM2 and the channel auxiliary layer CHM and an upper surface of the fourth insulating layer 124 between neighboring side surfaces of the first and second metal patterns CM1 and CM2 and the channel auxiliary layer CHM, and the first active layer ACT1 is disposed to be spaced apart from the second active layer ACT2.

In the second transistor T2 including the first and second metal patterns CM1 and CM2, as shown in FIGS. 10 to 13, the first and second metal patterns CM1 and CM2 may include first and second extension portions EXT1 and EXT2 protruding to the outside of the second active layer ACT2 such that the first and second metal patterns CM1 and CM2 are connected to the third and fourth source-drain electrodes SD21 and SD22 at the first and second extension portions EXT1 and EXT2, respectively. In this case, the second active layer ACT2 may be designed to have a length corresponding to a desired channel length, and both the first and second active layers ACT1 and ACT2 may be easily implemented to have minimal lengths, respectively.

In some cases, the display device may be implemented to configure a subpixel with both transistors having metal patterns by applying the structure of the first transistor T1 shown in FIG. 14 to a transistor functioning as a switching transistor, and applying the structure of the second transistor T2 shown in FIG. 15 to a transistor functioning as a driving transistor. In this case, since the metal patterns of the transistors may be fabricated using the same process, the manufacturing process is simplified, and amounts of materials such as gases, an etchant, etc. used throughout the manufacturing process is reduced, thereby reducing greenhouse gas emissions resulting from the manufacturing process.

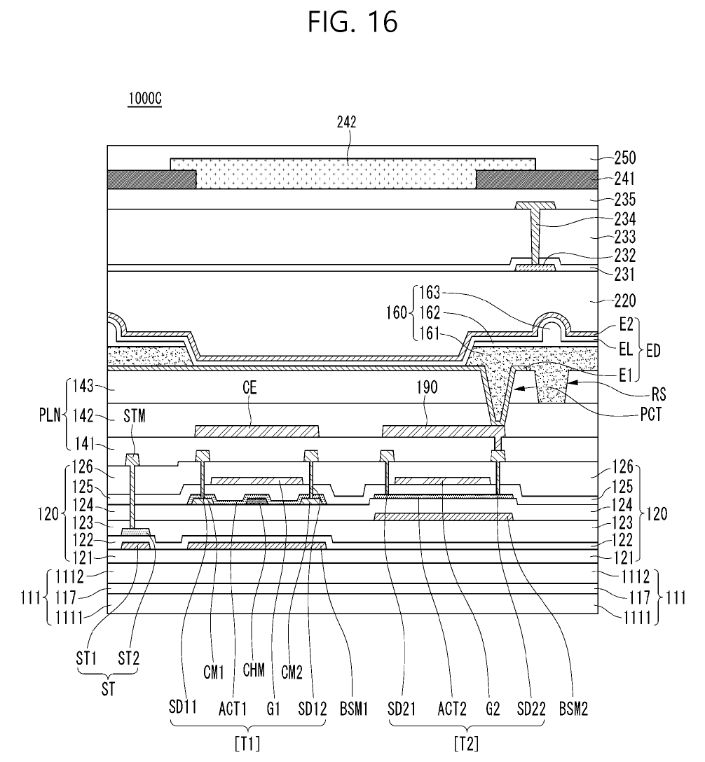

FIG. 16 is a cross-sectional view of a display device according to another implementation of the present disclosure.

A display device 1000C according to the implementation of FIG. 16 differs from the display device 1000A of FIG. 14 in that the transistor according to the second implementation described with reference to FIGS. 8 and 9 is applied to the first transistor T1.

The display device 1000C of FIG. 16 differs from the display device 1000A of FIG. 14 in terms of the first transistor T1, and is identical to the display device 1000A of FIG. 14 in terms of configurations disposed above and beneath the first and second transistors T1 and T2. Accordingly, no description of the same configurations will be given.

The first transistor T1 includes first and second metal patterns CM1 and CM2 disposed beneath a first active layer ACT1, and an additional channel auxiliary layer CHM disposed in a region between the first and second metal patterns CM1 and CM2.

In the display device 1000C shown in FIG. 16, the first transistor T1 may function as a switching transistor, and the second transistor T2 may function as a driving transistor.

In this case, the first transistor T1 includes the first active layer ACT1, which is provided on a substrate 111, a first metal pattern CM1 and a second metal pattern CM2 disposed beneath the first active layer ACT1 and spaced apart from each other by a first distance L in a first direction while overlapping with the first active layer ACT1, a first gate electrode G1 disposed on the first active layer ACT1 while overlapping with the first active layer ACT1 and having a width greater than the first distance L in the first direction under the condition that a fifth insulating layer 125 is interposed between the first active layer ACT1 and the first gate electrode G1, a first source-drain electrode SD11 connected to the first metal pattern CM1, and a second source-drain electrode SD12 connected to the second metal pattern CM2 and spaced apart from the first source-drain electrode SD11.

Additionally, in the first transistor T1, the channel auxiliary layer CHM, which is disposed at a central portion of a channel region on the same layer as that of the first and second metal patterns CM1 and CM2 to contact the first active layer ACT1, may be included.

The first metal pattern CM1 and the second metal pattern CM2 are layers provided beneath the first active layer ACT1 to contact the first active layer ACT1. The first metal pattern CM1 and the second metal pattern CM2 are directly connected to the first and second source-drain electrodes SD11 and SD12, respectively. Through this structure, the first gate electrode G1 is less restricted by a conductive region of the first active layer ACT1 and, as such, may be disposed to overlap with the entire region between the first and second metal patterns CM1 and CM2 and portions of the first and second metal patterns CM1 and CM2.

In some cases, as shown in FIGS. 10 to 13, the first and second metal patterns CM1 and CM2 may include first and second extension portions EXT1 and EXT2 protruding to the outside of the first active layer ACT1 such that the first and second metal patterns CM1 and CM2 are connected to the first and second source-drain electrodes SD11 and SD12 at the first and second extension portions EXT1 and EXT2, respectively.

The first and second metal patterns CM1 and CM2 have conductive properties, and the surface of the first active layer ACT1 facing the first and second metal patterns CM1 and CM2 may have low-resistance characteristics, as compared to other regions of the first active layer ACT1.

In the illustrated implementation, the first transistor T1 functioning as a switching transistor includes the first active layer ACT1 configured to contact the first and second metal patterns CM1 and CM2 at the lower surface thereof. The first transistor T1 further includes the channel auxiliary layer CHM and, as such, it may be possible to enhance high-speed driving of the first transistor T1.

A first light shielding pattern BSM1 may be provided beneath the first active layer ACT1. A plurality of insulating layers 122, 123, and 124 may be provided between the first active layer ACT1 and the first light shielding pattern BSM1. The plurality of insulating layers 122, 123, and 124 between the first active layer ACT1 and the first light shielding pattern BSM1 may function as a buffer layer configured to planarize a surface on which the first active layer ACT1 will be formed in association with the first transistor T1.

The first light shielding pattern BSM1 may be connected to the first gate electrode G1 in order to receive the same gate voltage signal as that of the first gate electrode G1. In accordance with this connection structure, the first light shielding pattern BSM1 and the first gate electrode G1 may be used as gate electrodes, respectively. Accordingly, high-speed driving of the first transistor T1 may be enhanced.

The second transistor T2 includes a second active layer ACT2 provided on the substrate 111, a second gate electrode G2 disposed on the second active layer ACT2 while overlapping with the second active layer ACT2 under the condition that the fifth insulating layer 125 is interposed between the second active layer ACT2 and the second gate electrode G2, and a third source-drain electrode SD21 and a fourth source-drain electrode SD22 connected to opposite sides of the second active layer ACT2, respectively.

As described above, each of the display devices 1000A, 1000B, and 1000C shown in FIGS. 14 to 16 includes, for at least one of the first and second transistors T1 and T2 provided at each subpixel, the transistor including the above-described first and second metal patterns configured to contact the active layer, as described with reference to FIGS. 5 to 13. This configuration may achieve a short channel length and may prevent a variation in effective channel length in the transistor structure. Formation of a conductive region (ΔL) overlapping with the gate electrode with reference to a designed channel length causes an increase in negative shift of a threshold voltage because the proportion of the conductive region (ΔL) relative to the designed total channel length becomes greater as the designed channel length becomes smaller. For this reason, it is difficult to obtain stable initial characteristics and dispersion characteristics of the transistor.

In the display devices according to the implementations of the present disclosure, the metallization process is omitted, and the channel length is defined by the distance between the first and second metal patterns disposed beneath the active layer, with less dependence on the exact shape and size of the gate electrode. Additionally, the conductive configuration directly contacts the active layer. Accordingly, it may be possible to stably secure characteristics of a short-channel transistor.

Since the first gate electrode G1 overlaps with the first and second metal patterns CM1 and CM2, removal of influence caused by hydrogen remaining over the first gate electrode G1 may be facilitated.

The channel auxiliary layer CHM, which includes a semiconductor material, is added to a central portion of the channel region CH as a high-mobility oxide for high-speed driving. Accordingly, it may be possible to achieve high-speed driving through the conductive portion when gate bias is applied.

As apparent from the above description, in the transistor and the display device according to each implementation of the present disclosure, first and second conductive metals spaced apart from each other are additionally provided beneath an active layer. Accordingly, the region between the first and second conductive metals is defined as a channel region of the active layer. Thus, a separate ion implantation or metallization process for formation of the channel region is not required, thereby simplifying the manufacturing process.

In a structure in which the channel region is defined through an additional metallization process after formation of the gate electrode, a great variation in effective channel length may occur. For this reason, the channel region is designed to have a great process margin, taking into account the effective channel length variation. As a result, there is a limitation in design of a channel with a short length. Differently from this structure, in the transistor and the display device according to each implementation of the present disclosure, the channel region may be defined through provision of conductive metals, with less dependence on the exact shape and size of the gate electrode. Accordingly, the effective channel length may be stabilized. When transistors with conductive metals are provided at a plurality of pixels on a substrate, it may be possible to prevent non-uniform variations in effective channel length among the plurality of pixels. Transistors disposed at the subpixels may also have uniform characteristics to have stable effective channels, respectively. As a result, dispersion characteristics of the transistors disposed on the substrate are stabilized, enabling reduced process margins and facilitating design of a channel with a short length.

In the transistor and the display device according to each implementation of the present disclosure, the transistor may be configured to include a gate electrode that is less restricted relative to a channel region and, as such, has design freedom of the gate electrode overlapping with the active layer. Since the channel region may be defined by a configuration disposed beneath the active layer, the gate electrode and first and second source-drain electrodes disposed over the active layer may have increased overlap areas with the active layer. This facilitates integrated design of the transistor.

In the transistor and the display device according to each implementation of the present disclosure, the gate electrode may be disposed to completely cover the active layer. Accordingly, it may be possible to effectively prevent the active layer from being affected by residual hydrogen in layers disposed over the gate electrode.

In the transistor and the display device according to each implementation of the present disclosure, the transistor may further include a channel auxiliary layer overlapping with the channel region in order to enable high-speed driving. As the transistor, which enables high-speed driving, is selectively provided at subpixels and a gate driver on the substrate, various transistors included in the substrate may achieve high-speed driving.

In the transistor and the display device according to each implementation of the present disclosure, it may be possible to reduce a defect rate of the transistor and to reduce amounts of materials such as gases, an etchant, etc. used throughout the manufacturing process for manufacture of the display device, thereby reducing greenhouse gas emissions resulting from the manufacturing process.

A transistor according to one implementation of the present disclosure may include an active layer, a first metal pattern and a second metal pattern disposed beneath the active layer and spaced apart from each other by a first distance in a first direction while overlapping with the active layer, a gate electrode disposed on the active layer while overlapping with the active layer and having a width along the first direction that is greater than the first distance, a gate insulating layer between the active layer and the gate electrode, a first source-drain electrode connected to the first metal pattern and a second source-drain electrode connected to the second metal pattern and spaced apart from the first source-drain electrode.

In a transistor according to one implementation of the present disclosure, a channel region of the active layer may have a channel length corresponding to the first distance in the first direction.

In a transistor according to one implementation of the present disclosure, the active layer may be in contact with the first metal pattern and the second metal pattern.

In a transistor according to one implementation of the present disclosure, the active layer may be disposed along steps of upper surfaces and side surfaces of the first metal pattern and the second metal pattern in a cross-sectional view.

In a transistor according to one implementation of the present disclosure, the gate electrode may completely overlap with a region between the first metal pattern and the second metal pattern in the first direction and overlap with a part of at least one of the first metal pattern or the second metal pattern.

In a transistor according to one implementation of the present disclosure, the first source-drain electrode and the second source-drain electrode may extend through the active layer and contact the first metal pattern and the second metal pattern, respectively.

In a transistor according to one implementation of the present disclosure, at least one of the first metal pattern and the second metal pattern may include an extension portion not overlapping with the active layer.

In a transistor according to one implementation of the present disclosure, the gate electrode may completely cover the active layer.

In a transistor according to one implementation of the present disclosure, the extension portion may include a first extension portion and a second extension portion protruding from opposite ends of the active layer, respectively. The first extension portion may be connected to the first source-drain electrode, and the second extension portion is connected to the second source-drain electrode.

A transistor according to one implementation of the present disclosure may further include a light shielding pattern overlapping with the active layer between the active layer and the substrate. The light shielding pattern and the gate electrode may be electrically connected to each other.

A transistor according to one implementation of the present disclosure may further include a light shielding pattern overlapping with the active layer between the active layer and the substrate. The light shielding pattern may be electrically connected to one of the first source-drain electrode and the second source-drain electrode.

In a transistor according to one implementation of the present disclosure, a buffer layer may be provided between the substrate and the active layer. An interlayer insulating layer may be provided between the gate electrode and the first and second source-drain electrodes. A first contact hole respectively overlapping with the first metal pattern and the first source-drain electrode and a second contact hole respectively overlapping with the second metal pattern and the second source-drain electrode may be provided in the interlayer insulating layer and the gate insulating layer.

In a transistor according to one implementation of the present disclosure, the first and second contact holes may be spaced apart from the gate electrode in a plan view, and at least one of the first source-drain electrode and the second source-drain electrode may include a portion overlapping with the gate electrode.

In a transistor according to one implementation of the present disclosure, the active layer may include an oxide semiconductor.

A transistor according to one implementation of the present disclosure may further include a channel auxiliary layer configured to contact the active layer between the first metal pattern and the second metal pattern.

In a transistor according to one implementation of the present disclosure, the channel auxiliary layer may include a semiconductor having higher mobility than the active layer.

A transistor according to one implementation of the present disclosure may further include at least one insulating layer between the active layer and the substrate. The first metal pattern, the second metal pattern, and the channel auxiliary layer may be disposed on the at least one insulating layer to contact the active layer.

A display device according to one implementation of the present disclosure may include a substrate including a plurality of subpixels, the transistor disposed in at least one of the plurality of subpixels, a planarization layer to cover the transistor and a light emitting element provided on the planarization layer and electrically connected to the transistor.

A display device according to one implementation of the present disclosure may include a substrate including an active area comprising a plurality of subpixels, and a non-active area surrounding the active area, a plurality of gate lines and a plurality of data lines intersecting each other at the plurality of sub-pixels, a light emitting element at each of the plurality of subpixels, a pixel transistor at least one of the plurality of subpixels; and a driver transistor connected to the plurality of gate lines and disposed at the non-active area. At least one of the pixel transistor and the driver transistor may include an active layer, a first metal pattern and a second metal pattern disposed beneath the active layer and spaced apart from each other by a first distance in a first direction while overlapping with the active layer, a gate electrode disposed on the active layer while overlapping with the active layer and having a width along the first direction that is greater than the first distance, a gate insulating layer between the active layer and the gate electrode, and source-drain electrodes connected to the first metal pattern and the second metal pattern, respectively.

In a display device according to one implementation of the present disclosure, the first metal pattern and the second metal pattern may contact the active layer at a same layer and the active layer may include an oxide semiconductor.

A display device according to one implementation of the present disclosure may further include a channel auxiliary layer configured to contact the active layer between the first metal pattern and the second metal pattern. The active layer may include an oxide semiconductor.

The channel auxiliary layer may include a semiconductor exhibiting higher mobility than the active layer.

The display device including the transistor according to implementations of the present disclosure may minimize a channel length margin of an active layer. It may realize reduced producing energy, reduced generation of harmful substance, and reduce a weight of the display device to provide a wide-width transistor. The display device may also control an effective channel length variation and reduce threshold voltage sensitivity to apply a high-power side-width transistor with a small size. Therefore, when a wide transistor is implemented in the display device, a channel length margin may be minimized, thereby a low power consumption is possible compared to a structure having a long channel length margin.

The display device according to implementation of the present disclosure has advantages of being environmentally and socially sustainable, thereby it may realize ESG (Environment/Social/Governance).

Although various example implementations of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. A transistor comprising:
an active layer on a substrate;
a first metal pattern and a second metal pattern disposed beneath the active layer and spaced apart from each other by a first distance in a first direction and overlapping with the active layer;
a gate electrode disposed on the active layer and overlapping with the active layer and having a width along the first direction that is greater than the first distance;
a gate insulating layer between the active layer and the gate electrode;
a first source-drain electrode connected to the first metal pattern; and
a second source-drain electrode connected to the second metal pattern and spaced apart from the first source-drain electrode.

2. The transistor according to claim 1, wherein a channel region of the active layer has a channel length corresponding to the first distance in the first direction, and
wherein an area of the channel region is smaller than an area of the gate electrode.

3. The transistor according to claim 1, wherein the active layer is in contact with upper surfaces and side surfaces of the first metal pattern and the second metal pattern in a cross-sectional view.

4. The transistor according to claim 1, wherein the gate electrode completely overlaps with a region between the first metal pattern and the second metal pattern in the first direction and overlaps with a part of at least one of the first metal pattern and the second metal pattern, and
wherein the gate electrode has a width greater than that of the active layer in a second direction crossing the first direction.

5. The transistor according to claim 1, wherein the first source-drain electrode and the second source-drain electrode are disposed above the gate electrode, and
wherein the first source-drain electrode and the second source-drain electrode extend through the gate insulating layer and the active layer and contact the first metal pattern and the second metal pattern, respectively.

6. The transistor according to claim 1, wherein at least one of the first metal pattern and the second metal pattern comprises at least one extension portion not overlapping with the active layer.

7. The transistor according to claim 6, wherein the gate electrode completely covers the active layer.

8. The transistor according to claim 6, wherein:
the first metal pattern comprises a first extension portion protruding from one end of the active layer, and the second metal pattern comprises a second extension portion protruding from another end of the active layer; and
the first extension portion is connected to the first source-drain electrode, and the second extension portion is connected to the second source-drain electrode.

9. The transistor according to claim 1, further comprising:
a light shielding pattern overlapping with the active layer and disposed between the active layer and the substrate,
wherein the light shielding pattern and the gate electrode are electrically connected to each other.

10. The transistor according to claim 1, further comprising:
a light shielding pattern overlapping with the active layer and disposed between the active layer and the substrate,
wherein the light shielding pattern is electrically connected to one of the first source-drain electrode and the second source-drain electrode.

11. The transistor according to claim 5, further comprising:
a buffer layer between the substrate and the active layer;
an interlayer insulating layer between the gate electrode and the first and second source-drain electrodes;
a first contact hole formed through the interlayer insulating layer and the gate insulating layer and overlapping with both the first metal pattern and the first source-drain electrode; and
a second contact hole formed through the interlayer insulating layer and the gate insulating layer and overlapping with both the second metal pattern and the second source-drain electrode,
wherein the first and second contact holes are spaced apart from the gate electrode in a plan view.

12. The transistor according to claim 5, wherein at least one of the first source-drain electrode and the second source-drain electrode comprises a portion overlapping with the gate electrode in a plan view.

14. The transistor according to claim 1, further comprising:
a channel auxiliary layer configured to contact the active layer between the first metal pattern and the second metal pattern,
wherein the channel auxiliary layer is disposed on a same layer as the first metal pattern and the second metal pattern.

15. The transistor according to claim 14, wherein the channel auxiliary layer comprises a semiconductor having higher mobility than the active layer.

16. The transistor according to claim 14, further comprising:
at least one insulating layer between the active layer and the substrate,
wherein the first metal pattern, the second metal pattern, and the channel auxiliary layer are disposed on the at least one insulating layer to contact the active layer.

17. A display device comprising:
a plurality of subpixels;
the transistor according to claim 1, the transistor disposed in at least one of the plurality of subpixels;
a planarization layer configured to cover the transistor; and
a light emitting element provided on the planarization layer.

18. A display device comprising:
a substrate comprising an active area comprising a plurality of subpixels, and a non-active area outside of the active area;
a plurality of gate lines and a plurality of data lines intersecting each other at the plurality of subpixels;
a plurality of light emitting elements disposed respectively at the plurality of subpixels;
a pixel transistor in at least one of the plurality of subpixels;
a driving circuit connected to the plurality of gate lines and disposed at the non-active area; and
a driver transistor disposed at the driving circuit,
wherein at least one of the pixel transistor and the driver transistor comprises:
an active layer on the substrate,
a first metal pattern and a second metal pattern disposed beneath the active layer and spaced apart from each other by a first distance in a first direction and overlapping with the active layer,
a gate electrode disposed on the active layer and overlapping with the active layer and having a width along the first direction that is greater than the first distance,
a gate insulating layer between the active layer and the gate electrode, and
source-drain electrodes connected to the first metal pattern and the second metal pattern, respectively.

19. The display device according to claim 18, wherein:
the first metal pattern and the second metal pattern both contact the active layer at a same layer; and
the active layer comprises an oxide semiconductor.

20. The display device according to claim 18, further comprising:
a channel auxiliary layer configured to contact the active layer between the first metal pattern and the second metal pattern,
wherein the active layer comprises an oxide semiconductor, and
wherein the channel auxiliary layer comprises a semiconductor exhibiting higher mobility than the active layer.
